(19) United States
(12) Patent Application Publication
(10) Pub. No.: US 2025/0023002 A1
(43) Pub. Date: Jan. 16, 2025

(54) DISPLAY DEVICE COMPRISING SEMICONDUCTOR LIGHT-EMITTING ELEMENT

(71) Applicants: LG ELECTRONICS INC., Seoul (KR); LG DISPLAY CO., LTD., Seoul (KR)

(72) Inventors: Youngdo KIM, Seoul (KR); Juhyun NAM, Paju-si (KR); Hun JANG, Paju-si (KR); Sul LEE, Paju-si (KR); Minseok KIM, Paju-si (KR); Hyeseon EOM, Paju-si (KR); Moonsun LEE, Paju-si (KR)

(73) Assignees: LG ELECTRONICS INC., Seoul (KR); LG DISPLAY CO., LTD., Seoul (KR)

(21) Appl. No.: 18/713,565

(22) PCT Filed: Oct. 11, 2022
(86) PCT No.: PCT/KR2022/015292

§ 371 Date: May 24, 2024

(30) Foreign Application Priority Data
Nov. 26, 2021 (KR) 10-2021-0166160

(51) Int. Cl. H01L 33/62; H01L 33/38

(52) U.S. Cl. CPC H01L 33/62; H01L 33/382

(57) ABSTRACT

A display device including a semiconductor light emitting device according to an embodiment may include a substrate, a first assembly wiring and a second assembly wiring arranged to be spaced apart from each other on the substrate, a planarization layer disposed on the first assembly wiring and the second assembly wiring and having an opening overlapping the first assembly wiring and the second assembly wiring, a light emitting device including a first electrode placed inside the opening and electrically connected to the first assembly wiring, and wherein the opening includes a main opening and one or more auxiliary openings that are connected to the main opening and are smaller than the main opening.

### TECHNICAL FIELD

The embodiment relates to a display device, and more specifically, to a display device using a semiconductor light emitting device.

### BACKGROUND ART

Display devices used in computer monitors, TVs, mobile phones, etc. include Organic Light Emitting Display (OLED), which emits light on its own, Liquid Crystal Display (LCD), and Micro-LED display, which require a separate light source.

Micro-LED display is a display that uses micro-LED, a semiconductor light emitting device with a diameter or cross-sectional area of 100 μm or less, as a display device.

Micro-LED displays use micro-LED, a semiconductor light emitting device, as a display device, so they have excellent performance in many characteristics such as contrast ratio, response speed, color gamut, viewing angle, brightness, resolution, lifespan, luminous efficiency, and luminance.

In particular, the micro-LED display has the advantage of being able to freely adjust the size and resolution and implement a flexible display because the screen may be separated and combined in a modular manner.

However, because large micro-LED displays require more than millions of micro-LEDs, there is a technical problem that makes it difficult to quickly and accurately transfer micro-LEDs to the display panel. Meanwhile, methods for transferring a semiconductor light emitting device to a substrate include a pick and place process, a laser lift-off method, or a self-assembly method.

Among these, the self-assembly method is a method in which a semiconductor light emitting device finds its assembly position within a fluid on its own, and is an advantageous method for implementing a large-screen display device.

Meanwhile, when a light emitting device is transferred in a fluid, there is a problem of the assembly wiring being corroded by the fluid. Corrosion of the assembly wiring may cause an electrical short circuit and cause assembly defects. Additionally, for smooth self-assembly, it is important to secure the contact area between the assembly wiring and the light emitting device.

### DISCLOSURE

### Technical Problem The technical object of the embodiment is to provide a display device that improves the assembly rate of the light emitting device by implementing assembly wiring in various forms.

Additionally, the technical object of the embodiment is to provide a display device that minimizes corrosion of assembly wiring.

In addition, the technical object of the embodiment is to provide a display device that may easily bond a light emitting device by reducing the step between assembly wirings.

In addition, the technical object of the embodiment is to provide a display device that improves the electric field concentration phenomenon by reducing the size of the first electrode of the light emitting device.

In addition, the technical object of the embodiment is to provide a display device that may easily bond a light emitting device by changing the shape of the first electrode and opening of the light emitting device.

Additionally, the technical object of the embodiment is to provide a display device in which side wiring that drives a light emitting device is formed uniformly.

In addition, the technical object of the embodiment is to provide a display device with improved assembly ability of a light emitting device.

The objects of the embodiment are not limited to the objects mentioned above, and other objects not mentioned will be clearly understood by those skilled in the art from the description below.

### Technical Solution

A display device having a semiconductor light emitting device according to an embodiment including a substrate; a first assembly wiring and a second assembly wiring arranged to be spaced apart from each other on the substrate; a planarization layer disposed on the first assembly wiring and the second assembly wiring and having an opening overlapping the first assembly wiring and the second assembly wiring; and a light emitting device disposed inside the opening and including a first electrode electrically connected to the first assembly wiring, wherein the opening may include a main opening and one or more auxiliary openings that are connected to the main opening and are smaller than the main opening.

Additionally, in an embodiment, the first assembly wiring is disposed above the second assembly wiring, the first electrode is in contact with the first assembly wiring, and the auxiliary opening may overlap the first assembly wiring.

Additionally, in an embodiment, an area where the first assembly wiring and the opening overlap may be wider than the area where the second assembly wiring and the opening overlap.

In addition, in the embodiment, the first assembly wiring and the second assembly wiring are arranged on the same layer,

The light emitting device further includes a first semiconductor layer disposed on the first electrode and having a bottom surface that is larger in area than the top surface of the first electrode, wherein the first electrode may be arranged asymmetrically with respect to the center of the first semiconductor layer.

Additionally, in an embodiment, an end of the first electrode may be disposed on a same plane as an end of the first semiconductor layer, or may protrude outward from the end of the first semiconductor layer.

Additionally, in an embodiment, the auxiliary opening may be arranged adjacent to the end of the first electrode.

Additionally in an embodiment may further include a passivation layer disposed between the first assembly wiring, the second assembly wiring, and the light emitting device, and including a contact hole for exposing the first assembly wiring disposed between the light emitting device and the planarization layer; and a contact electrode connecting the first electrode and the first assembly wiring through the contact hole.

Additionally, in an embodiment, the main opening and the light emitting device may have a circular or oval shape in a plane.

Additionally, in an embodiment, the auxiliary openings may be arranged in plural numbers to surround the main opening.

Additionally, in an embodiment, the main opening and the light emitting device may have the same polygonal shape on a plane.

Additionally, in an embodiment, the auxiliary opening may be arranged to be connected to a plurality of vertices or a plurality of sides of the main opening.

In addition, a display device having a semiconductor light emitting device according to an embodiment includes a substrate in which a plurality of sub pixels are defined; a plurality of first assembly wirings arranged along a plurality of sub pixels arranged on the same line among the plurality of sub pixels; a plurality of second assembly wirings arranged along a plurality of sub pixels arranged on the same line among the plurality of sub pixels and arranged adjacent to each of the first assembly wirings; a planarization layer including a plurality of pockets overlapping the plurality of first assembly wirings and the plurality of second assembly wirings; and a plurality of light emitting devices disposed in the plurality of pockets in each of the plurality of sub pixels and including a lower electrode connected to a display device, wherein each of the plurality of pockets may include a first pocket having a first size in which the plurality of light emitting devices are disposed, and a second pocket having a second size smaller than the first size and extending from the first pocket.

Additionally, in an embodiment, the plurality of first assembly wirings are disposed above the plurality of second assembly wirings, and the lower electrode is in contact with the plurality of first assembly wirings,

The second pocket may overlap the plurality of first assembly wiring.

Additionally, in an embodiment, the plurality of first assembly wirings and the plurality of second assembly wirings may be arranged on the same plane.

Additionally, in an embodiment, the light emitting device includes a first semiconductor layer disposed on the lower electrode, the lower electrode has a smaller planar area than the first semiconductor layer, and the lower electrode may be arranged asymmetrically with respect to the center of the first semiconductor layer.

Additionally, in an embodiment, the end of the lower electrode may coincide with the side of the light emitting device or may protrude outward from the side of the light emitting device.

Additionally, in an embodiment, the second pocket may be arranged adjacent to the end of the lower electrode.

Additionally, in an embodiment, the second pocket may be arranged in plurality to surround the outside of the first pocket.

In addition, in the embodiment, the first assembly wiring and the second assembly wiring vertically overlap, and the first assembly wiring may include an electrode hole in a region that vertically overlaps the second assembly wiring and the light emitting device.

In addition, a display device including a semiconductor light emitting device according to an embodiment includes a substrate;

First assembly wiring and second assembly wiring arranged to be spaced apart from each other on the substrate;

A planarization layer disposed on the first assembly wiring and the second assembly wiring and having an opening overlapping the first assembly wiring and the second assembly wiring;

A light emitting device disposed within the opening and including a first electrode;

A side wiring disposed within the opening and electrically connected to the first electrode;

The opening includes a main opening and one or more auxiliary openings connected to the main opening and smaller than the main opening,

The side wiring is disposed within the auxiliary opening and may be in contact with the side wall of the opening.

### Advantageous Effects

According to the embodiment, there is a technical effect in that wiring for self-assembly of a light emitting device may also be used as wiring for driving the light emitting device.

In addition, the embodiment has the technical effect of minimizing defects during self-assembly or bonding of a light emitting device by forming the structure of a plurality of assembly wiring in various ways.

Additionally, the embodiment has the technical effect of minimizing corrosion and short circuit defects in a plurality of assembly wiring.

Additionally, the embodiment has the technical effect of stably bonding a plurality of light emitting devices by reducing the level difference between the plurality of assembly wirings.

In addition, the embodiment has the technical effect of reducing the area of the first electrode of the light emitting device and securing a wide electric field gradient to form an electric field symmetrically.

In addition, the embodiment has the technical effect of reducing assembly defects of the light emitting device by preventing the electric field from being focused on the partition wall on the side of the opening by changing the shape of the first electrode and opening of the light emitting device.

Additionally, the embodiment has the technical effect of forming uniform side wiring by changing the shape of the opening.

Additionally, the embodiment has the technical effect of improving the assembly force for a light emitting device by arranging a plurality of assembly wirings to overlap vertically.

The effects according to the embodiment are not limited to the contents exemplified above, and more diverse effects are included in the specification.

### DESCRIPTION OF DRAWINGS

FIG. 1 is a schematic plan view of a display device according to an embodiment.

FIG. 2 is a schematic enlarged plan view of a display device according to an embodiment.

FIG. 3 is an enlarged plan view of area A of FIG. 2.

FIG. 4 is a cross-sectional view taken along line IV-IV′ of FIG. 2.

FIGS. 5A to 5F are process diagrams for explaining a manufacturing method of a display device according to an embodiment.

FIG. 6 is an enlarged plan view of the display device according to the second embodiment.

FIG. 7 is a cross-sectional view of a display device according to a second embodiment.

FIG. 8A is an enlarged plan view of a display device according to a third embodiment.

FIG. 8B is an enlarged plan view of a display device according to the fourth embodiment.

FIG. 8C is an enlarged plan view of a display device according to the fifth embodiment.

FIG. 9 is an enlarged plan view of a display device according to the sixth embodiment.

FIGS. 10A to 11B are enlarged plan views of display devices according to seventh to tenth embodiments.

FIG. 12 is an enlarged plan view of a display device according to the 11th embodiment.

FIG. 13 is an enlarged plan view of a display device according to the twelfth embodiment.

FIG. 14 is an enlarged perspective view of a portion of the display device according to the twelfth embodiment.

### MODE FOR INVENTION

Hereinafter, embodiments disclosed in this specification will be described in detail with reference to the attached drawings. The suffixes ‘module’ and ‘part’ for components used in the following description are given or used interchangeably in consideration of ease of specification preparation, and do not have distinct meanings or roles in themselves. In addition, the attached drawings are intended to facilitate easy understanding of the embodiments disclosed in this specification, and the technical ideas disclosed in this specification are not limited by the attached drawings. Additionally, when an element such as a layer, region or substrate is referred to as being ‘on’ another component, this includes either directly on the other element or there may be other intermediate elements in between.

Display devices described in this specification include digital TVs, mobile phones, smart phones, laptop computers, digital broadcasting terminals, personal digital assistants (PDAs), portable multimedia players (PMPs), navigation, slate PCs, tablet PCs, ultra-books, desktop computers, etc. However, the configuration according to the embodiment described in this specification may be applied to a device capable of displaying, even if it is a new product type that is developed in the future.

Hereinafter, an embodiment will be described with reference to the drawings.

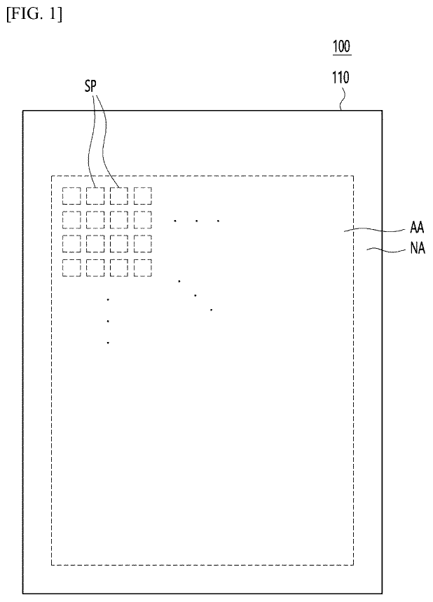

FIG. 1 is a schematic plan view of a display device according to the embodiment. In FIG. 1, for convenience of explanation, only the substrate 110 and a plurality of sub pixels SP are shown among the various components of the display device 100.

The display device 100 according to the embodiment may include a flexible display manufactured on a thin and flexible substrate. Flexible displays may bend or curl like paper while maintaining the characteristics of existing flat displays.

In a flexible display, visual information may be implemented by independently controlling the light emission of unit pixels arranged in a matrix form. A unit pixel refers to the minimum unit for implementing one color. A unit pixel of a flexible display may be implemented by a light-emitting device. In the embodiment, the light emitting device may be Micro-LED or Nano-LED, but is not limited thereto.

The substrate 110 is configured to support various components included in the display device 100, and may be made of an insulating material. For example, the substrate 110 may be made of glass or resin. Additionally, the substrate 110 may include polymer or plastic, or may be made of a material with flexibility.

The substrate 110 includes a display area AA and a non-display area NA.

The display area AA is an area where a plurality of sub pixels SP are arranged and an image is displayed. Each of the plurality of sub pixels SP is an individual unit that emits light, and a light emitting device LED and a driving circuit are formed in each of the plurality of sub pixels SP. For example, the plurality of sub pixels SP may include a red sub pixel, a green sub pixel, a blue sub pixel, and/or a white sub pixel, but are not limited thereto. Hereinafter, the description will be made assuming that the plurality of sub pixels SP includes a red sub pixel, a green sub pixel, and a blue sub pixel, but is not limited thereto.

The non-display area NA is an area where images are not displayed, and is an area where various wiring, driver ICs, etc. are placed to drive the sub pixels SP arranged in the display area AA. For example, various ICs, such as gate driver ICs and data driver ICs, and driving circuits may be placed in the non-display area NA. Meanwhile, the non-display area NA may be located on the back of the substrate 110, that is, on the side without sub pixels SP. or may be omitted, and is not limited to what is shown in the drawing.

The display device 100 of the embodiment may drive the light emitting device in an active matrix (AM, Active Matrix) method or a passive matrix (PM, Passive Matrix) method.

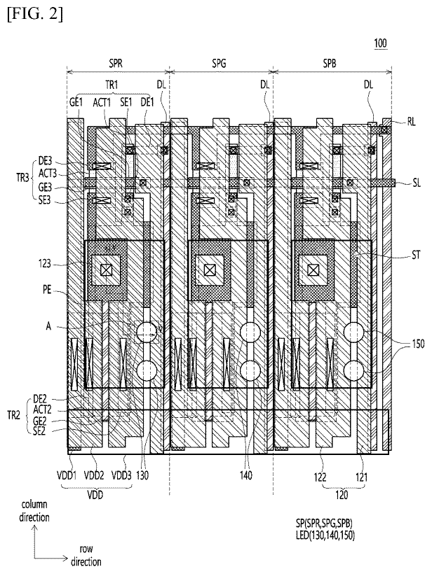

Hereinafter, FIGS. 2 to 4 will be referred to for a more detailed description of the plurality of sub pixels SP.

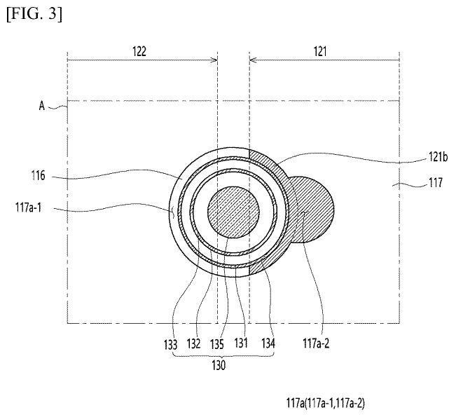

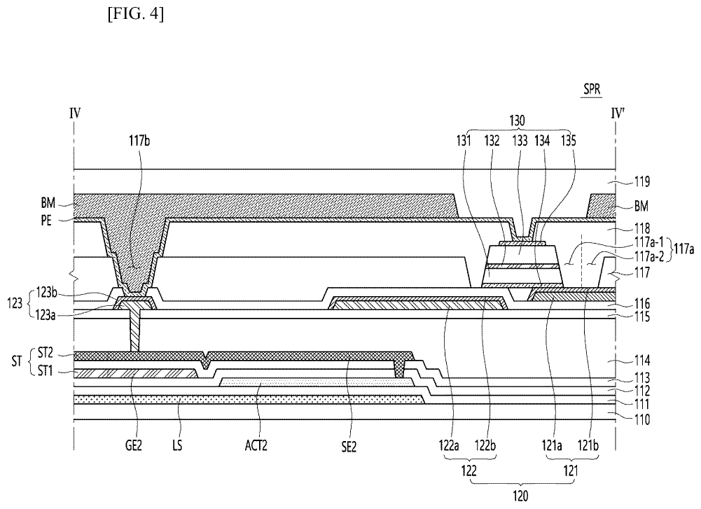

FIG. 2 is a schematic enlarged plan view of a display device according to an embodiment. FIG. 3 is an enlarged plan view of area A of FIG. 2. FIG. 4 is a cross-sectional view taken along line IV-IV′ of FIG. 2. Referring to FIGS. 2 to 4, the display device 100 according to an embodiment may include a plurality of scan lines SL, a plurality of data lines DL, a plurality of high potential power supply wirings VDD, a plurality of assembly wiring 120, a plurality of reference lines RL and
a plurality of reference line RL and a black matrix BM, a first transistor TR1, a second transistor TR2, a third transistor TR3 for each of the plurality of sub pixels SP, a storage capacitor ST, a semiconductor light emitting device LED, a light blocking layer LS, a buffer layer 111, a gate insulating layer 112, a plurality of passivation layers 113, 115 and 116, a plurality of planarization layers 114, 117 and 118, connection electrodes 123, and pixel electrodes PE, etc.

Referring to FIGS. 2 and 4, a plurality of data lines DL, a first layer VDD1 and a second layer VDD2 of high potential power supply wiring VDD, a plurality of reference lines RL and a plurality of assembly wirings 120 extend in a column direction between a plurality of sub pixels SP, and a third layer VDD3 of the plurality of scan lines SL and the high potential power supply wiring VDD may extend in the row direction between the plurality of sub pixels SP. Additionally, a first transistor TR1, a second transistor TR2, a third transistor TR3, and a storage capacitor ST may be disposed in each of the plurality of sub pixels SP.

First, the first layer VDD1 of the high potential power supply wiring VDD and the light blocking layer LS may be disposed on the substrate 110.

The high potential power supply wiring VDD is a wiring that transmits a high potential power supply voltage to each of a plurality of sub pixels SP. The plurality of high potential power supply wirings VDD may transmit a high potential power supply voltage to the second transistor TR2 of each of the plurality of sub pixels SP.

Meanwhile, a plurality of high potential power wiring VDD may be made of a single layer or multiple layers, hereinafter, for convenience of explanation, the description will be made on the assumption that a plurality of high potential power supply wirings VDDs are composed of a plurality of layers.

The high potential power supply wiring VDD includes a plurality of first layers VDD1, a plurality of second layers VDD2, and a plurality of third layers VDD3 connecting them. The first layer VDD1 may extend in the column direction between each of the plurality of sub pixels SP.

A light blocking layer LS may be disposed in each of a plurality of sub pixels SP on the substrate 110. The light blocking layer LS may minimize leakage current by blocking light incident from the lower portion of the substrate 110 to the second active layer ACT2 of the second transistor TR2, which will be described later.

The buffer layer 111 is disposed on the first layer VDD1 of the high potential power supply wiring VDD and the light blocking layer LS. The buffer layer 111 may reduce the penetration of moisture or impurities through the substrate 110. The buffer layer 111 may be composed of, for example, a single layer or a multiple layer of silicon oxide (SiOx) or silicon nitride (SiNx), but is not limited thereto. However, the buffer layer 111 may be omitted depending on the type of substrate 110 or the type of transistor, but is not limited thereto.

A plurality of a scan lines SL, a plurality of a reference lines RL, a plurality of a data lines DL, a first transistor TR1, a second transistor TR2, a third transistor TR3, and a storage capacitor ST may be disposed on a buffer layer 111.

First, the first transistor TR1 may be disposed in each of a plurality of sub pixels SP. The first transistor TR1 includes a first active layer ACT1, a first gate electrode GE1, a first source electrode SE1, and a first drain electrode DE1. The first active layer ACT1 is disposed on the buffer layer 111. The first active layer ACT1 may be made of a semiconductor material such as oxide semiconductor, amorphous silicon, or polysilicon, but is not limited thereto.

The gate insulating layer 112 may be disposed on the first active layer ACT1. The gate insulating layer 112 is an insulating layer for insulating the first active layer ACT and the first gate electrode GE1, and may be composed of a single layer or multiple layers of silicon oxide (SiOx) or silicon nitride (SiNx), but it is not limited to this.

The first gate electrode GE1 may be disposed on the gate insulating layer 112. The first gate electrode GE1 may be electrically connected to the scan line SL. The first gate electrode GE1 may be made of a conductive material, such as, copper (Cu), aluminum (Al), molybdenum (Mo), nickel (Ni), titanium (Ti), chromium (Cr), or an alloy thereof, but is not limited thereto.

The first passivation layer 113 may be disposed on the first gate electrode GE1. Contact holes are formed in the first passivation layer 113 to connect the first source electrode SE1 and the first drain electrode DEI to the first active layer ACT. The first passivation layer 113 is an insulating layer to protect the structure below the first passivation layer 113, and may be composed of a single layer or multiple layers of silicon oxide (SiOx) or silicon nitride (SiNx), but is limited thereto.

A first source electrode SE1 and a first drain electrode DEI electrically connected to the first active layer ACT may be disposed on the first passivation layer 113. The first drain electrode DE1 may be connected to the data line DL, and the first source electrode SE1 may be connected to the second gate electrode GE2 of the second transistor TR2. The first source electrode SE1 and the first drain electrode DE1 may be made of a conductive material, such as, copper (Cu), aluminum (Al), molybdenum (Mo), nickel (Ni), titanium (Ti), chromium (Cr), or an alloy thereof, but is not limited thereto.

Meanwhile, in the embodiment, it has been described that each of the first source electrode SE1 and the first drain electrode DE1 is connected to the second gate electrode GE2 and the data line DL. However, depending on the type of transistor, the first source electrode SE1 may be connected to the data line DL, and the first drain electrode DE1 may be connected to the second gate electrode GE2 of the second transistor TR2, but are not limited thereto.

The first gate electrode GE1 of the first transistor TR1 is connected to the scan line SL and may be turned on or off depending on the scan signal. The first transistor TR1 may transmit a data voltage to the second gate electrode GE2 of the second transistor TR2 based on the scan signal, and may be referred to as a switching transistor.

Meanwhile, a plurality of data lines DL and a plurality of reference lines RL may be disposed on the gate insulating layer 112 along with the first gate electrode GE1. The plurality of data lines DL and the reference lines RL may be formed of the same material and process as the first gate electrode GE1.

The plurality of data lines DL are wires that transmit data voltage to each of the plurality of sub pixels SP. The plurality of data lines DL may transmit data voltage to the first transistor TR1 of each of the plurality of sub pixels SP. For example, the plurality of data lines DL may be made of a data line DL that transmits data voltage to the red sub pixel SPR, a data line DL that transmits data voltage to the green sub pixel SPG and a data line DL that transmits data voltage to the blue sub pixel SPB.

A plurality of reference lines RL are wires that transmit a reference voltage to each of a plurality of sub pixels SP. The plurality of reference lines RL may transmit the reference voltage to the third transistor TR3 of each of the plurality of sub pixels SP.

The second transistor TR2 may be disposed in each of the plurality of sub pixels SP. The second transistor TR2 may include a second active layer ACT2, a second gate electrode GE2, a second source electrode SE2, and a second drain electrode DE2. The second active layer ACT2 may be disposed on the buffer layer 111. The second active layer ACT2 may be made of a semiconductor material such as oxide semiconductor, amorphous silicon, or polysilicon, but is not limited thereto.

The gate insulating layer 112 may be disposed on the second active layer ACT2, and the second gate electrode GE2 may be disposed on the gate insulating layer 112. The second gate electrode GE2 may be electrically connected to the first source electrode SE1 of the first transistor TR1. The second gate electrode GE2 may be made of a conductive material, such as copper (Cu), aluminum (Al), molybdenum (Mo), nickel (Ni), titanium (Ti), chromium (Cr), or an alloy thereof, but is not limited thereto.

The first passivation layer 113 may be disposed on the second gate electrode GE2, and the second source electrode SE2 and the second drain electrode DE2 may be disposed on the first passivation layer 113. The second source electrode SE2 is electrically connected to the second active layer ACT2. The second drain electrode DE2 may be electrically connected to the second active layer ACT2 and at the same time may be electrically connected to the high potential power supply wiring VDD. The second drain electrode DE2 may be disposed between the first layer VDD1 and the second layer VDD2 of the high potential power supply wiring VDD and electrically connected to the high potential power supply wiring VDD.

Since the second gate electrode GE2 of the second transistor TR2 is connected to the first source electrode SE1 of the first transistor TR1, when the first transistor TR1 is turned on, it may be turned on by the data voltage transmitted. And the turned on second transistor TR2 may transfer the driving current to the light emitting device LED based on the high potential power supply voltage from the high potential power supply wiring VDD, so it may be referred to as a driving transistor.

The third transistor TR3 may be disposed in each of the plurality of sub pixels SP. The third transistor TR3 may include a third active layer ACT3, a third gate electrode GE3, a third source electrode SE3, and a third drain electrode DE3. The third active layer ACT3 may be disposed on the buffer layer 111. The third active layer ACT3 may be made of a semiconductor material such as oxide semiconductor, amorphous silicon, or polysilicon, but is not limited thereto.

The gate insulating layer 112 may be disposed on the third active layer ACT3, and the third gate electrode GE3 may be disposed on the gate insulating layer 112. The third gate electrode GE3 is connected to the scan line SL, and the third transistor TR3 may be turned on or off by the scan signal. The third gate electrode GE3 may be made of a conductive material, such as copper (Cu), aluminum (Al), molybdenum (Mo), nickel (Ni), titanium (Ti), chromium (Cr), or an alloy thereof, but is not limited thereto.

However, it was explained that the third gate electrode GE3 and the first gate electrode GE1 are connected to the same scan line SL, however, the third gate electrode GE3 may be connected to a different scan line SL from the first gate electrode GE1, but is not limited thereto.

The first passivation layer 113 may be disposed on the third gate electrode GE3, and the third source electrode SE3 and the third drain electrode DE3 may be disposed on the first passivation layer 113. The third source electrode SE3 is formed integrally with the second source electrode SE2, and may be electrically connected to the third active layer ACT3 and simultaneously to the second source electrode SE2 of the second transistor TR2. And the third drain electrode DE3 may be electrically connected to the reference line RL.

The third transistor TR3 electrically connected to the second source electrode SE2. reference line RL, and storage capacitor ST of the second transistor TR2, which is a driving transistor, may be referred to as a sensing transistor.

A storage capacitor ST may be disposed in each of a plurality of sub pixels SP. The storage capacitor ST may include a first capacitor electrode ST1 and a second capacitor electrode ST2. The storage capacitor ST is connected between the second gate electrode GE2 and the second source electrode SE2 of the second transistor TR2, by storing the voltage, the voltage level of the gate electrode of the second transistor TR2 may be maintained constant while the light emitting device LED emits light.

The first capacitor electrode ST1 may be integrated with the second gate electrode GE2 of the second transistor TR2. Accordingly, the first capacitor electrode ST1 may be electrically connected to the second gate electrode GE2 of the second transistor TR2 and the first source electrode SE1 of the first transistor TR1.

The second capacitor electrode ST2 is disposed on the first capacitor electrode ST1 with the first passivation layer 113 interposed therebetween. The second capacitor electrode ST2 may be integrated with the second source electrode SE2 of the second transistor TR2 and the third source electrode SE3 of the third transistor TR3. Accordingly, the second capacitor electrode ST2 may be electrically connected to the second transistor TR2 and the third transistor TR3.

Meanwhile, the plurality of scan lines SL may be disposed on a first passivation layer 113 with a first source electrode SE1, a first drain electrode DE1, a second source electrode SE2, a second drain electrode DE2, a third source electrode SE3, a third drain electrode DE3 and a second capacitor electrode ST2.

The plurality of scan lines SL are wires that transmit scan signals to each of the plurality of sub pixels SP. The plurality of scan lines SL may transmit scan signals to the first transistor TR1 of each of the plurality of sub pixels SP. For example, each of the plurality of scan lines SL extends in the row direction and may transmit a scan signal to a plurality of sub pixels SP arranged in the same row.

Next, the first planarization layer 114 may disposed on a plurality of scan lines SL, a plurality of reference lines RL, a plurality of data lines DL, a first transistor TR1, a second transistor TR2, a third transistor TR3 and storage capacitor ST. The first planarization layer 114 may planarize the upper portion of the substrate 110 on which a plurality of transistors are disposed. The first planarization layer 114 may be composed of a single layer or a double layer, and may be made of, for example, an acryl-based organic material, but is not limited thereto.

The second passivation layer 115 may be disposed on the first planarization layer 114. The second passivation layer 115 is an insulating layer for protecting the structure below the second passivation layer 115 and improving the adhesion of the structure formed on the second passivation layer 115, so the second passivation layer 115 may be composed of a single layer or multiple layers of silicon oxide (SiOx) or silicon nitride (SiNx), but is not limited thereto.

The second layer VDD2 of the high potential power supply wiring VDD, a plurality of second assembly wirings 122 among the plurality of assembly wirings 120 and the connection electrode 123 may be disposed on the second passivation layer 115.

First, the plurality of assembly wiring 120 generates an electric field for aligning the plurality of light emitting devices LED when manufacturing the display device 100, and supplies low-potential power voltage to a plurality of light emitting devices LED when the display device 100 is driven. Accordingly, the assembly wiring 120 may be referred to as low-potential power wiring. A plurality of assembly wirings 120 are arranged in a column direction along a plurality of sub pixels SP arranged on the same line. A plurality of assembly wiring 120 may be arranged to overlap a plurality of sub pixels SP arranged in the same column. For example, a first assembly wiring 121 and a second assembly wiring 122 are arranged in a red sub pixel SPR arranged in the same row, one first assembly wiring 121 and one second assembly wiring 122 are placed in the green sub pixel SPG, one first assembly wiring 121 and one second assembly wiring 122 are placed in the green sub pixel SPG, and one first assembly wiring 121 and one second assembly wiring 122 may be arranged in the blue sub pixel SPB.

The plurality of assembly wirings 120 may include a plurality of first assembly wirings 121 and a plurality of second assembly wirings 122. When the display device 100 is driven, the same low-potential voltage may be applied to the plurality of first assembly wirings 121 and the plurality of second assembly wirings 122 in alternating current. The plurality of first assembly wirings 121 and the plurality of second assembly wirings 122 may be alternately arranged. And in each of the plurality of sub pixels SP, one first assembly wiring 121 and one second assembly wiring 122 may be arranged adjacent to each other.

The plurality of first assembly wirings 121 and the plurality of second assembly wirings 122 may be made of a conductive material, for example, copper (Cu) and chromium (Cr), but are not limited thereto.

The plurality of second assembly wirings 122 may include a second conductive layer 122a and a second clad layer 122b. The second conductive layer 122a may be disposed on the second passivation layer 115. The second clad layer 122b may be in contact with the second conductive layer 122a. For example, the second clad layer 122b may be disposed to cover the top and side surfaces of the second conductive layer 122a. And the second conductive layer 122a may have a thickness greater than that of the second clad layer 122b.

Since the second clad layer 122b is made of a material that is more resistant to corrosion than the second conductive layer 122a, when manufacturing the display device 100, there is a technical effect of minimizing short circuit defects caused by migration between the second conductive layer 122a of the second assembly wiring 122 and the first conductive layer 121a of the first assembly wiring 121.

A second layer VDD2 of high potential power supply wiring VDD may be disposed on the second passivation layer 115. The second layer VDD2 extends in the column direction between each of the plurality of sub pixels SP and may overlap the first layer VDD1 The first layer VDD1 and the second layer VDD2 may be electrically connected through a contact hole formed in the insulating layers formed between the first layer VDD1 and the second layer VDD2. The second layer VDD2 may be formed of the same material and the same process as the second assembly wiring 122, but is not limited thereto.

The connection electrode 123 may be disposed in each of a plurality of sub pixels SP. The connection electrode 123 is electrically connected to the second capacitor electrode ST2 and the second source electrode SE2 of the second transistor TR2 through a contact hole formed in the second passivation layer 115. The connection electrode 123 is an electrode for electrically connecting a light emitting device LED and the second transistor TR2, which is a driving transistor, and includes a first connection layer 123a and a second connection layer 123b. For example, the first connection layer 123a may be formed of the same material on the same layer as the second conductive layer 122a of the second assembly wiring 122, and the second connection layer 123b may be formed of the same material as the second clad layer 122b on the same layer.

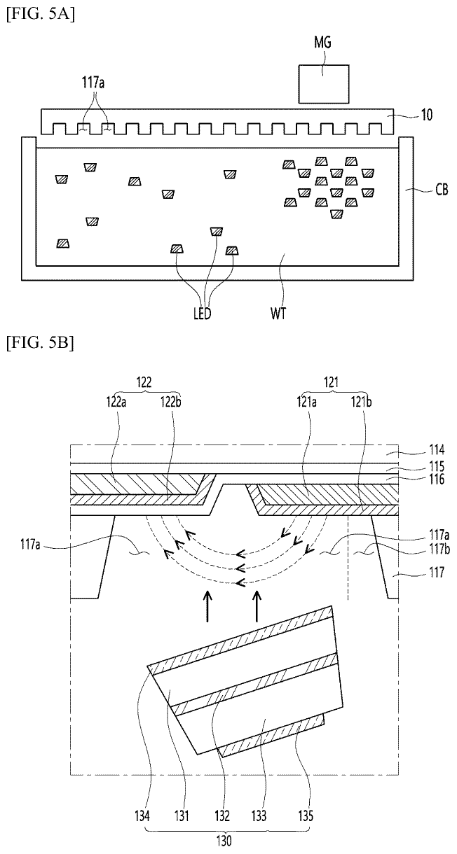

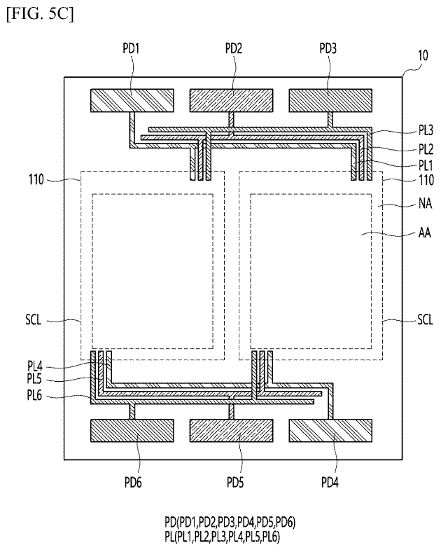

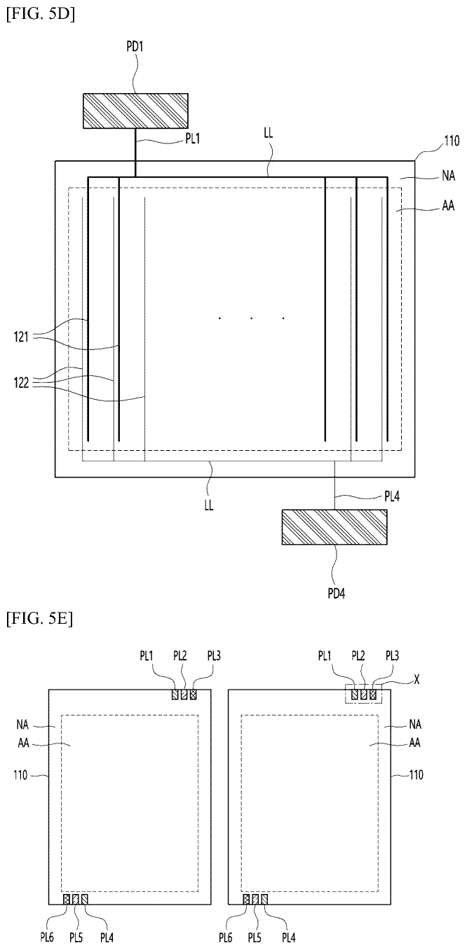

Subsequently, the third passivation layer 116 may be disposed on the second layer VDD2, the second assembly wiring 122, and the connection electrode 123. The third passivation layer 116 is an insulating layer to protect the structure below the third passivation layer 116, and may be composed of a single layer or multiple layers of silicon oxide (SiOx) or silicon nitride (SiNx), but is not limited thereto. In addition, the third passivation layer 116 may function as an insulating layer to prevent short circuit defects due to migration between the first assembly wiring 121 and the second assembly wiring 122 when manufacturing the display device 100, and this will be described later with reference to FIGS. 5A to 5F.

The plurality of first assembly wirings 121 among a plurality of assembly wirings 120 are disposed on the third passivation layer 116. Each of the plurality of first assembly wirings 121 is arranged in a plurality of sub pixels SP arranged on the same line as described above, and the plurality of first assembly wirings 121 and the plurality of second assembly wirings 122 may be arranged to be spaced apart from each other.

Each of the plurality of first assembly wirings 121 includes a first conductive layer 121a and a first clad layer 121b. The first conductive layer 121a is disposed on the third passivation layer 116. And the first clad layer 121b may be electrically connected to the first conductive layer 121a. For example, the first clad layer 121b may be disposed to cover the top and side surfaces of the first conductive layer 121a. And the first conductive layer 1211a may have a thickness greater than that of the first clad layer 121b.

Since the first clad layer 121b, like the second clad layer 122b, is also made of a material that is more resistant to corrosion than the first conductive layer 121a, when manufacturing the display device 100, short circuit defects due to migration between the first assembly wiring 121 and the second assembly wiring 122 may be minimized. For example, the first clad layer 121b may be made of molybdenum (Mo), molybdenum titanium (MoTi), etc., but is not limited thereto.

Next, the second planarization layer 117 may be disposed on the plurality of first assembly wirings 121. The second planarization layer 117 may be composed of a single layer or a double layer, and may be made of, for example, an acryl-based organic material, but is not limited thereto.

Meanwhile, the second planarization layer 117 may include a plurality of first openings 117a on which each of a plurality of light emitting devices LED is seated, and a plurality of second openings 117b exposing each of a plurality of connection electrodes 123.

The plurality of first openings 117a may be disposed in each of a plurality of sub pixels SP. Here, the first opening may be referred to as a pocket. Each of the plurality of first openings 117a may include a main opening 117a-1 and an auxiliary opening 117a-2. At this time, more than one first opening 117a may be arranged in one sub pixel SP. For example, one first opening 117a may be placed in one sub pixel SP, or two first openings 117a may be placed in one sub pixel SP.

The plurality of first openings 117a may be formed to overlap the plurality of assembly wirings 120. For example, one first opening 117a may overlap the first assembly wiring 121 and the second assembly wiring 122 arranged adjacent to each other in one sub pixel SP.

And at the first opening 117a, a portion of the first clad layer 121b of the plurality of first assembly wirings 121 may be exposed. On the other hand, in the first opening 117a, the third passivation layer 116 covers all of the second assembly wiring 122, so the second assembly wiring 122 overlaps the first opening 117a, but is not is not exposed at the first opening 117a.

The main opening 117a-1 is an opening into which a plurality of light emitting devices LED are inserted, and may also be referred to as a first pocket. At this time, the main opening 117a-1 and the plurality of light emitting devices LED may have circular or oval shapes corresponding to each other on a plane as shown in FIG. 3, but are not limited thereto.

The auxiliary opening 117a-2 may be connected to the main opening 117a-1. The auxiliary opening 117a-2 may also be referred to as a second pocket. At this time, more than one auxiliary opening 117a-2 connected to one main opening 117a-1 may be arranged. For example, one auxiliary opening 117a-2 may be connected to one main opening 117a-1, or two or more auxiliary openings 117a-2 may be connected to one main opening 117a-1. In the display device 100 according to the embodiment, a case where there is only one auxiliary opening 117a-2 will be described.

Referring to FIG. 3, the auxiliary opening 117a-2 may be connected to the main opening 117a-1 into which a light emitting device LED is inserted. However, the auxiliary opening 117a-2 is smaller than the main opening 117a-1, so the plurality of light emitting devices LED may not be inserted. At this time, the auxiliary opening 117a-2 may have a circular or oval shape on a plane. Additionally, the planar shape of the auxiliary opening 117a-2 may correspond to the planar shape of the main opening 117a-1.

The auxiliary opening 117a-2 may be formed to overlap a plurality of assembly wiring 120. However, the auxiliary opening may overlap only one of the first assembly wiring 121 and the second assembly wiring 122. For example, as shown in FIGS. 3 and 4, one auxiliary opening 117a-2 may overlap only with the first assembly wiring 121 among the first assembly wiring 121 and the second assembly wiring 122 arranged adjacent to each other in one sub pixel SP. Accordingly, the area where the first assembly wiring 121 and the first opening 117a overlap may be wider than the area where the second assembly wiring 122 and the first opening 117a overlap.

A plurality of second openings 117b may be arranged in a plurality of sub pixels SP. The plurality of second openings 117b are parts that expose the connection electrodes 123 of each of the plurality of sub pixels SP. The connection electrode 123 below the second planarization layer 117 is exposed at the plurality of second openings 117b and may be electrically connected to a light emitting device LED, and the driving current from the second transistor TR2 may be transferred to a light emitting device LED. The connection electrode 123 below the second planarization layer 117 is exposed at the plurality of second openings 117b and may be electrically connected to a light emitting device LED, and the driving current from the second transistor TR2 may be transferred to a light emitting device LED. At this time, the third passivation layer 116 may have a contact hole in the area overlapping the second opening 117b, and the connection electrode 123 may be exposed from the second planarization layer 117 and the third passivation layer 116.

The plurality of light emitting devices LED are disposed in the plurality of first openings 117a. The plurality of light emitting devices LED are light emitting devices LED that emit light by electric current. The plurality of light emitting devices LED may include light emitting devices LED that emit red light, green light, blue light, etc., and the combination of these may produce light of various colors, including white. For example, the light emitting device LED may be, but is not limited to, a Light Emitting Diode LED or micro LED.

Hereinafter, the description will be made assuming that it includes a red light emitting device 130 in which a plurality of light emitting devices LED are arranged in a red sub pixel SPR, a green light emitting device 140 disposed in a green sub pixel SPG and a blue light emitting device 150 disposed in a blue sub pixel SPB. However, the plurality of light emitting devices LED are composed of light emitting devices LED that emit light of the same color, and images of various colors may be displayed using a separate light conversion member that converts light from a plurality of light emitting devices LED into light of different colors, but is not limited thereto.

The plurality of light emitting devices LED may include a red light emitting device 130 placed in a red sub pixel SPR, a green light emitting device 140 placed in a green sub pixel SPG, and a blue light emitting device 150 placed in a blue sub pixel SPB. Each of the red light emitting device 130, green light emitting device 140, and blue light emitting device 150 may include a first semiconductor layer, a second semiconductor layer, a first electrode, and a second electrode in common. And the red light emitting device 130 may include a light emitting layer that emits red light, the green light emitting device 140 may include a light emitting layer that emits green light, and the blue light emitting device 150 may include a light emitting layer that emits blue light.

Referring to FIG. 4, the red light emitting device 130 disposed in the red sub pixel SPR has a second semiconductor layer 133 disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may include an AlInGaP-based semiconductor layer, and for example, it may be a layer doped with a p-type or n-type impurity in a material such as indium aluminum phosphide (InAlP) or gallium arsenide (GaAs). And the p-type impurity may be magnesium MG, zinc (Zn), beryllium (Be), etc., and the n-type impurity may be silicon (Si), germanium (Ge), tin (Sn), etc., but is not limited thereto.

A light emitting layer 132 that emits red light is disposed between the first semiconductor layer 131 and the second semiconductor layer 133. The light emitting layer 132 may emit light by receiving holes and electrons from the first semiconductor layer 131 and the second semiconductor layer 133. The light emitting layer 132 may be made of a single-layer or multi-quantum well (MQW) structure, and may be made of, for example, indium gallium nitride (InGaN) or gallium nitride (GaN), but is not limited thereto.

The first electrode 134 is placed on a bottom of the first semiconductor layer 131, and the second electrode 135 is placed on the top of the second semiconductor layer 133. Accordingly, the first electrode 134 may be referred to as a lower electrode. The first electrode 134 is an electrode bonded to the first assembly wiring 121 exposed at the first opening 117a, and the second electrode 135 is an electrode that electrically connects a pixel electrode PE, which will be described later, and the second semiconductor layer 133. The first electrode 134 and the second electrode 135 may be formed of a conductive material.

At this time, in order to bond the first electrode 134 to the first assembly wiring 121, the first electrode 134 may be made of a eutectic metal. For example, the first electrode 134 may be made of tin (Sn), indium (In), zinc (Zn), lead (Pb), nickel (Ni), gold (Au), platinum (Pt), copper (Cu), etc., but is not limited thereto.

And both the green light emitting device 140 and the blue light emitting device 150 may be formed in the same structure as the red light emitting device 130 For example, the green light emitting device 140 may include a first electrode, a first semiconductor layer on the first electrode, a green light-emitting layer on the first semiconductor layer, a second semiconductor layer on the green light-emitting layer, and a second electrode on the second semiconductor layer, and the blue light emitting device may also have a structure in which a first electrode, a first semiconductor layer, a blue light emitting layer, a second semiconductor layer, and a second electrode are sequentially stacked.

However, the green light emitting device 140 and the blue light emitting device 150 may be formed of a compound selected from the group consisting of GaN, AlGaN, InGaN, AlInGaN, GaP, AlN, GaAs, AlGaAs, InP, and mixtures thereof, but are not limited thereto.

Meanwhile, although not shown in the drawing, an insulating layer surrounding a portion of each of the plurality of light emitting devices LED may be disposed. Specifically, the insulating layer may cover at least the side surface of the light emitting device LED among the outer surfaces of the plurality of light emitting devices LED. By forming an insulating layer on the light emitting device LED, the light emitting device LED is protected, when forming the first electrode 134 and the second electrode 135, electrical short circuit between the first semiconductor layer 131 and the second semiconductor layer 133 may be prevented.

Next, the third planarization layer 118 may be disposed on a plurality of light emitting devices LED. The third planarization layer 118 may planarize the upper part of the substrate 110 on which a plurality of light emitting devices LED are arranged, and the plurality of light emitting devices LED may be stably fixed in the first opening 117a by the third planarization layer 118. The third planarization layer 118 may be composed of a single layer or a double layer, and may be made of, for example, an acryl-based organic material, but is not limited thereto.

The pixel electrode PE may be disposed on the third planarization layer 118. The pixel electrode PE is an electrode for electrically connecting a plurality of light emitting devices LED and the connection electrode CE. The pixel electrode PE may be electrically connected to the light emitting device LED of the first opening 117a and the connection electrode 123 of the second opening 117b through a contact hole formed in the third planarization layer 118. Accordingly, the second electrode 135, the connection electrode 123, and the second transistor TR2 of the light emitting device LED may be electrically connected through the pixel electrode PE.

A third layer VDD3 of high potential power supply wiring VDD may be disposed on the third planarization layer 118. The third layer VDD3 may electrically connect the first layer VDD1 and the second layer VDD2 arranged in different rows. For example, the third layer VDD3 extends in the row direction between a plurality of sub pixels SP, the plurality of second layers VDD2 of high potential power supply wiring VDD extending in a column direction may be electrically connected to each other. And as the plurality of high potential power supply wiring VDD is connected in a mesh form through the third layer VDD3, the voltage drop phenomenon may be reduced.

A black matrix BM may be disposed on the third planarization layer 118. The black matrix BM may be disposed between the plurality of sub pixels SP on the third planarization layer 118. The black matrix BM may reduce color mixing between plurality of sub pixels SP. The black matrix BM may be made of an opaque material, for example, black resin, but is not limited thereto.

A protective layer 119 may be disposed on the pixel electrode PE, the third planarization layer 118, and the black matrix BM. The protective layer 119 is a layer to protect the structure below the protective layer 119, and may be composed of a single layer or multiple layers of translucent epoxy, silicon oxide (SiOx), or silicon nitride (SiNx), but is not limited thereto.

Meanwhile, in the first opening 117a, the plurality of second assembly wirings 122 are spaced apart from the plurality of light emitting devices LED, and only the plurality of first assembly wirings 121 may contact the plurality of light emitting devices LED. In order to prevent a problem in which a plurality of light emitting devices LED contact both the first plurality of assembly wirings 121 and the plurality of second assembly wirings 122 during the manufacturing process of the display device 100, the third passivation layer 116 may be formed on the plurality of second assembly wirings 122, and a plurality of light emitting devices LED may be contacted only to the first plurality of assembly wirings 121.

FIGS. 5A to 5F are process diagrams for explaining a manufacturing method of a display device according to an embodiment. FIGS. 5A and 5B are process diagrams for explaining a process of self-assembling a plurality of light emitting devices LED into the first opening 117a. FIG. SC is a schematic plan view of the mother substrate 10 used for self-assembly of a plurality of light emitting devices LED. FIG. 5D is a diagram schematically showing the electrical connection relationship between a plurality of assembly wirings 120 and the assembly pad PD. FIG. 5E is a schematic plan view of a plurality of substrates 110 formed by scribing the mother substrate 10 after self-assembly of a plurality of light emitting devices LED is completed. FIG. 5F is a schematic cross-sectional view of area X in FIG. 5E.

Referring to FIG. 5A, a light emitting device LED is introduced into the chamber CB filled with the fluid WT. The fluid WT may include water, etc., and the chamber CB filled with the fluid WT may have an open top.

Next, the mother substrate 10 may be placed on the chamber CB filled with a light emitting device LED. A mother substrate 10 is a substrate composed of a plurality of substrates 110 forming a display device 100, when self-assembling the plurality of light emitting devices LED, the mother substrate 10 formed with a plurality of assembly wirings 120 and a second planarization layer 117 may be used.

And, the mother substrate 10 formed up to the first assembly wiring 121, the second assembly wiring 122, and the second planarization layer 117 is placed on the chamber CB or inserted into the chamber CB.

Then, the magnet MG may be placed on the mother substrate 10. Light emitting devices LED that sink or float on the bottom of the chamber CB may move toward the mother substrate 10 by the magnetic force of the magnet MG.

At this time, the light emitting device LED may include a magnetic material to move by a magnetic field. For example, the first electrode 134 or the second electrode 135 of a light emitting device LED may include a ferromagnetic material such as iron, cobalt, or nickel.

Next, the light emitting device LED moved to the second planarization layer 117 by the magnet MG may be self-assembled in the first opening 117a by the electric field formed by the first assembly wiring 121 and the second assembly wiring 122.

An alternating voltage may be applied to the plurality of first assembly wirings 121 and the plurality of second assembly wirings 122 to form an electric field. Due to this electric field, a light emitting device LED may be dielectrically polarized and have polarity. And a dielectrically polarized light emitting device LED may be moved or fixed in a specific direction by dielectrophoresis (DEP), that is, an electric field. Therefore, a plurality of light emitting devices LED may be fixed within the first opening 117a of the second planarization layer 117 using dielectrophoresis.

Next, The mother substrate 10 may be flipped 180 degrees while the light emitting device LED is fixed within the first opening 117a using the electric fields of the plurality of first assembly wirings 121 and the plurality of second assembly wirings 122. If the mother substrate 10 is turned over without applying voltage to the plurality of first assembly wirings 121 and the plurality of second assembly wirings 122, the plurality of light emitting devices LED may escape from within the first opening 117a. Therefore, with voltage applied to the plurality of first assembly wirings 121 and the plurality of second assembly wirings 122, the mother substrate 10 may be turned over and a subsequent process may be performed.

And with the first electrode 134 of the light emitting device LED located on the first assembly wiring 121, the light emitting device LED may be bonded to the first assembly wiring 121 by applying heat and pressure to the light emitting device LED. For example, the first electrode 134 of a light emitting device LED may be bonded to the first assembly wiring 121 through eutectic bonding. Eutectic bonding is a bonding method using heat compression at high temperatures and is one of the bonding processes that is very strong and highly reliable. The eutectic bonding method not only realizes high bonding strength, but also has the advantage of eliminating the need to apply a separate adhesive from the outside. However, the bonding method of a plurality of light emitting devices LED may be configured in various ways other than eutectic bonding, but is not limited thereto.

Meanwhile, different voltages are applied to the plurality of first assembly wirings 121 and the plurality of second assembly wirings 122 when manufacturing the display device 100, but the same voltage is applied in alternating current when the display device 100 is driven. For this, when manufacturing the display device 100, the plurality of first assembly wirings 121 and the plurality of second assembly wirings 122 may be connected to different assembly pads PD and different voltages may be applied.

In this regard, referring to FIG. 5C, when manufacturing the display device 100, in the state of the mother substrate 10, assembly wiring 120 on the plurality of substrates 110 may be connected to assembly pads PD outside the plurality of substrates 110. Specifically, a plurality of substrates 110 forming the display device 100, a plurality of assembly pads PD, and a plurality of assembly wiring connection parts PL are disposed on the mother substrate 10.

The plurality of assembly pads PD are pads for applying voltage to the plurality of assembly wirings 120, so the plurality of assembly pads PD may be electrically connected to a plurality of assembly wirings 120 disposed on each of the plurality of substrates 110 forming the mother substrate 10. The plurality of assembly pads PD may be formed on the mother substrate 10 outside the substrate 110 of the display device 100, and it may be separated from the substrate 110 of the display device 100 when the manufacturing process of the display device 100 is completed. For example, when two substrates 110 are formed on the mother substrate 10, the plurality of first assembly wirings 121 arranged on each substrate 110 may be connected to one assembly pad PD, and a plurality of second assembly wirings 122 may be connected to another assembly pad PD.

Therefore, after placing the mother substrate 10 in the chamber CB into which a plurality of light emitting devices LED are inserted, an electric field may be formed by applying an alternating voltage to a plurality of assembly wirings 120 through a plurality of assembly pads PD, and the plurality of light emitting devices LED may be easily self-assembled into the first opening 117a of the second planarization layer 117.

On the other hand, when self-assembling the plurality of light emitting devices LED for each sub pixel SP, the plurality of assembly wiring 120 arranged in a plurality of red sub pixels SPR, the plurality of assembly wiring 120 arranged in a plurality of green sub pixels SPG and the plurality of assembly wirings 120 arranged in a plurality of blue sub pixels SPB may be connected to different assembly pads PD respectively.

In this case, the plurality of assembly pads PD may include a first assembly pad PD1, a second assembly pad PD2, a third assembly pad PD3, a fourth assembly pad PD4, a fifth assembly pad PDS and a sixth assembly pad PD6.

The first assembly pad PD1 is a pad for applying voltage to a plurality of first assembly wirings 121 arranged in a plurality of red sub pixels SPR on the mother substrate 10. The fourth assembly pad PD4 is a pad for applying voltage to a plurality of second assembly wirings 122 arranged in a plurality of red sub pixels SPR on the mother substrate 10.

The second assembly pad PD2 is a pad for applying voltage to a plurality of first assembly wirings 121 arranged in a plurality of green sub pixels SPG on the mother substrate 10. The fifth assembly pad PDS is a pad for applying voltage to a plurality of second assembly wirings 122 arranged in a plurality of green sub pixels SPG on the mother substrate 10.

The third assembly pad PD3 is a pad for applying voltage to a plurality of first assembly wirings 121 arranged in a plurality of blue sub pixels SPB on the mother substrate 10. The sixth assembly pad PD6 is a pad for applying voltage to a plurality of second assembly wirings 122 arranged in a plurality of blue sub pixels SPB on the mother substrate 10.

Through these plurality of assembly pads PD, a light emitting device LED may be selectively self-assembled only in a specific sub pixel SP among the plurality of sub pixels SP. For example, when self-assembling a light emitting device LED only in the plurality of red sub pixels SPR, voltage may be applied only to the plurality of first assembly wirings 121 and the plurality of second assembly wirings 122 arranged in the plurality of red sub pixels SPR through the first assembly pad PD1 and the fourth assembly pad PD4.

The assembly wiring connection portion PL is a wiring connecting a plurality of assembly wirings 120 and a plurality of assembly pads PD on each substrate 110. An assembly wiring connection portion PL is connected at one end to a plurality of assembly pads PD, and another end may extend onto the plurality of substrates 110 and be electrically connected to the plurality of first assembly wirings 121 and the plurality of second assembly wirings 122. The assembly wiring connection part PL includes a first connection part PL1, a second connection part PL2, a third connection part PL3, a fourth connection part PL4, a fifth connection part PL5, and a sixth connection part PL6.

The first connection part PL1 is a wire that electrically connects the first assembly wiring 121 disposed in a plurality of red sub pixels SPR on the mother substrate 10 and the first assembly pad PD1. The fourth connection portion PL4 is a wiring that electrically connects the second assembly wiring 122 disposed in a plurality of red sub pixels SPR on the mother substrate 10 and the fourth assembly pad PD4. For example, the another end of the first connection portion PL1 extends to each of the plurality of substrates 110, and the plurality of substrates 110 may be electrically connected to a plurality of first assembly wirings 121 disposed in each red sub pixel SPR. For example, another end of the fourth connection portion PL4 extends to each of the plurality of substrates 110, and the plurality of substrates 110 may be electrically connected to a plurality of second assembly wirings 122 disposed in each red sub pixel SPR.

The second connection part PL2 is a wire that electrically connects the first assembly wiring 121 disposed in a plurality of green sub pixels SPG on the mother substrate 10 and the second assembly pad PD2. The fifth connection portion PL5 is a wiring that electrically connects the second assembly wiring 122 disposed in a plurality of green sub pixels SPG on the mother substrate 10 and the fifth assembly pad PD5.

The third connection portion PL3 is a wiring that electrically connects the first assembly wiring 121 disposed in a plurality of blue sub pixels SPB on the mother substrate 10 and the third assembly pad PD3. The sixth connection portion PL6 is a wiring that electrically connects the second assembly wiring 122 disposed in a plurality of blue sub pixels SPB on the mother substrate 10 and the sixth assembly pad PD6.

At this time, a plurality of first assembly wirings 121 arranged on one substrate 110 are connected into one, and the plurality of second assembly wirings 122 may also be connected into one, so that each of the plurality of first assembly wirings 121 and the plurality of second assembly wirings 122 may be easily connected to the assembly wiring connection portion PL.

For example, referring to FIG. 5D, the first assembly wiring 121 arranged in a plurality of red sub pixels SPR in one substrate 110 is connected to one through a link wire LL in the non-display area NA of the substrate 110, and the second assembly wiring 122 arranged in a plurality of red sub pixels SPR may also be connected to one another through a link wire LL in the non-display area NA of the substrate 110. In this case, each of the plurality of first assembly wirings 121 and the plurality of second assembly wirings 122 arranged on one substrate 110 is not individually connected to the assembly wiring connection portion PL, in the non-display area NA, a link line LL connecting each of the plurality of first assembly wirings 121 and the plurality of second assembly wirings 122 into one and the assembly wiring connection portion PL are connected to each other, so the voltage for self-assembly of a light emitting device LED may be easily applied to the plurality of first assembly wirings 121 and the plurality of second assembly wirings 122.

Meanwhile, the assembly wiring connection portion PL may be formed of the same material and the same process as the plurality of assembly wirings 120, or may be formed of different materials and processes. Additionally, the assembly wiring connection portion PL may have a single-layer structure or a multi-layer structure, but is not limited thereto.

In addition, the assembly wiring connection portion PL and assembly pad PD shown in FIGS. 5C and 5D are exemplary, and an assembly wiring may vary depending on the arrangement and shape of the connection part PL and assembly pad PD, the number or sequence of self-assembly processes, and the design of multiple sub pixels SP.

Next, referring to FIGS. 5E and 5F, after the self-assembly process of the plurality of light emitting devices LED is completed, the mother substrate 10 may be cut along the scribing line (SCL) and separated into a plurality of substrates 110. In addition, when scribing the mother substrate 10, a portion of the assembly wiring connection portion PL connecting the plurality of assembly wirings 120 and the plurality of assembly pads PD at the edge of the substrate 110 may be cut. Accordingly, the cut surface of the assembly wiring connection portion PL may be confirmed from the cut surface of the substrate 110.

For example, in area X of FIG. 5E, a cross section of the substrate 110, a cross section of a plurality of insulating layers IL disposed to form a driving circuit or a plurality of wires on the substrate 110, and a cross section of the assembly wiring connection portion PL disposed between the plurality of insulating layers IL may be confirmed. A first connection portion PL1 connecting the first assembly wiring 121 of the plurality of red sub-pixels SPR between the plurality of insulating layers IL, a second connection part PL2 connecting the first assembly wiring 121 of a plurality of green sub pixels SPG, and a cut surface of the third connection part PL3 connecting the first assembly wiring 121 of the plurality of blue sub pixels SPB may be seen.

Meanwhile, after scribing the mother substrate 10 and separating it into a plurality of substrates 110, through a link line LL connecting a plurality of first assembly wirings 121 into one and a link line LL connecting a plurality of second assembly wirings 122 into one, the same voltage may be easily applied to the plurality of first assembly wirings 121 and the plurality of second assembly wirings 122. For example, when driving the display device 100, voltage may be applied to the plurality of first assembly wirings 121 and the plurality of second assembly wirings 122 by connecting the link line LL connecting each of the plurality of first assembly wirings 121 and the plurality of second assembly wirings 122 into one in the non-display area NA and the driving IC.

In the display device 100 according to the embodiment, at least some of the assembly wiring 120 for self-assembly of the plurality of light emitting devices LED may be used as wiring for applying a low-potential power supply voltage to the plurality of light emitting devices LED. When manufacturing the display device 100, the plurality of light emitting devices LED floating in the fluid WT may be moved adjacent to the mother substrate 10 using a magnetic field. Next, different voltages may be applied to the plurality of first assembly wirings 121 and the plurality of second assembly wirings 122 to form an electric field, and the plurality of light emitting devices LED may be self-assembled within the plurality of first openings 117a by an electric field. At this time, instead of forming a separate wiring that supplies low-potential voltage and connecting it to the plurality of self-assembled light emitting devices LED, by bonding the first electrode 134 of the light emitting device LED to the first assembly wiring 121, a portion of which is exposed within the first opening 117a, when driving the display device 100, a plurality of assembly wirings 120 may be used as wiring for supplying low-potential voltage to the plurality of light emitting devices LED. Therefore, in the display device 100 according to the embodiment, there is a technical effect in that the plurality of assembly wirings 120 may be used not only for self-assembly of a plurality of light emitting devices LED but also as wiring for driving a plurality of light emitting devices LED.

In the display device 100 according to the embodiment, the plurality of assembly wirings 120 include a clad layer, so that corrosion of the plurality of assembly wirings 120 or short circuit defects may be reduced. The plurality of first assembly wirings 121 are composed of a first conductive layer 121a and a first clad layer 121b that surrounds the first conductive layer 121a and is more resistant to corrosion than the first conductive layer 121a, and the plurality of second assembly wirings 122 includes a second conductive layer 122a and a second clad layer 122b that surrounds the second conductive layer 122a and is more resistant to corrosion than the second conductive layer 122a. When manufacturing the display device 100, a plurality of light emitting devices LED may be self-assembled by placing the mother substrate 10 on which a plurality of assembly wirings 120 are formed within the fluid WT.

In this case, the first conductive layer 121a and/or the second conductive layer 122a may be exposed in the fluid WT and the assembly wiring 120 may be corroded, which may cause a short circuit defect. Therefore, the second conductive layer 122a of the plurality of second assembly wirings 122 may be wrapped with the second passivation layer 115 and the second clad layer 122b, and the first conductive layer 121a of the plurality of first assembly wirings 121 may be wrapped with the third passivation layer 116 and the first clad layer 121b. Accordingly, the plurality of assembly wirings 120 are formed in a structure including the first clad layer 121b and the second clad layer 122b, which has a technical effect of improving the reliability of the plurality of assembly wirings 120.

Meanwhile, in the internally researched technology, in order to assemble a plurality of light emitting devices, a first opening was formed in the second planarization layer to correspond to the shape and size of the light emitting device. Here, when forming the first opening to correspond to the size of the light emitting device, the first opening is formed to the minimum size that allows the light emitting device to be assembled within the first opening, taking process margin into consideration. When the first opening is formed to correspond to the shape and size of the light emitting device, the space between the second planarization layer and the light emitting device was narrow, and the area of the first assembly wiring exposed by the second planarization layer was narrow, resulting in a high assembly defect rate. In addition, when applying voltage to the first assembly wiring and the second assembly wiring to form an electric field to self-assemble the light emitting device, the space between the second planarization layer and the light emitting device is narrow, so a strong electric field may be formed in that space, accordingly, a phenomenon in which the electric field is asymmetrically focused may occur. At this time, there is a problem in that the electric field is focused on the second planarization layer, which is the side of the opening, causing an assembly defect in which the light emitting device gets on the second planarization layer. Therefore, when increasing the overall size of the first opening, there is a problem in that the size of the first opening is excessively increased compared to the light emitting device, and the light emitting device may be separated from the first opening after self-assembly of the light emitting device, and the resolution of the display device may be reduced.

Accordingly, in the display device 100 according to the embodiment, first opening 117a where a light emitting device LED is inserted may include a main opening 117a-1 corresponding to the shape and size of the light emitting device LED and an auxiliary opening 117a-2 extending from the main opening 117a-1. The auxiliary opening 117a-2 is smaller than the main opening 117a-1, so a light emitting device LED is not inserted, but in the area where the auxiliary opening 117a-2 is placed, sufficient space may be secured between the light emitting device LED and the second planarization layer 117. Accordingly, the area of the first assembly wiring 121 exposed by the main opening 117a-1 and the auxiliary opening 117a-2 is expanded, so the area where the light emitting device LED may contact the first assembly wiring 121 is also expanded, and then there is a technical effect in that a sufficient contact area between the light emitting device LED and the first assembly wiring 121 may be secured and assembly defects may be improved.

In particular, in the display device 100 according to the embodiment, the first assembly wiring 121 is disposed above the second assembly wiring 122, and the first electrode 134 of the light emitting device 130 is in contact with the first assembly wiring 121. Therefore, since the first assembly wiring 121 and the second assembly wiring 122 are placed on different layers rather than the same layer, the electric field asymmetry phenomenon may become more severe, and the electric field may be stronger in the space between the first assembly wiring 121 and the second planarization layer 117 exposed to the first opening 117a.

Accordingly, in the display device 100 according to the embodiment, as the first opening 117a includes an auxiliary opening 117a-2 connected to the main opening 117a-1, a sufficient space between the second planarization layer 117 and the light emitting device LED may be secured. Accordingly, by placing an additional auxiliary opening 117a-2 in an area where the electric field may be concentrated more strongly, sufficient space may be secured between the second planarization layer 117 and the light emitting device LED, so as the intensity per unit area of the electric field decreases, the electric field asymmetry phenomenon may become weaker.

Therefore, in the display device 100 according to the embodiment, there is a technical effect that assembly defects, such as the light emitting device LED getting on the second planarization layer 117, may be improved due to the asymmetrical electric field.

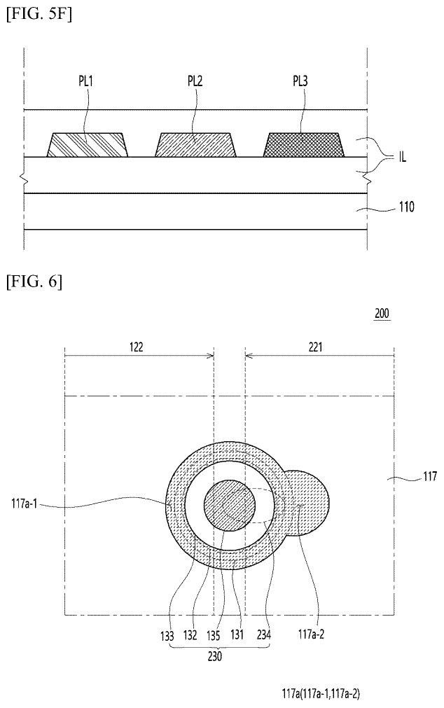

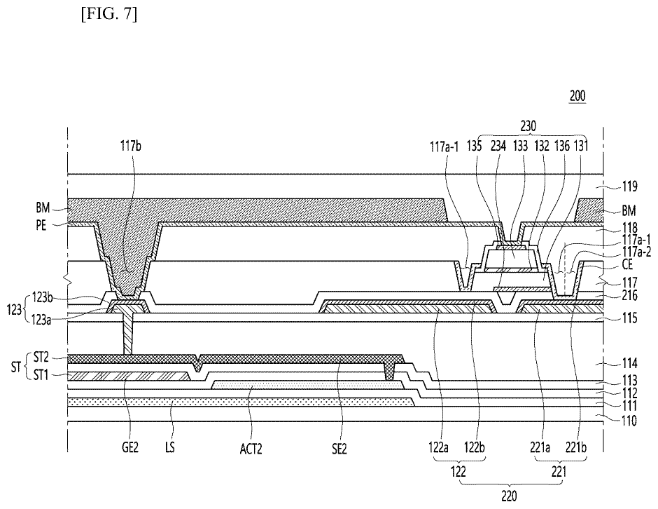

FIG. 6 is a schematic enlarged plan view of a display device according to a second embodiment. FIG. 7 is a cross-sectional view of a display device according to a second embodiment. Referring to FIGS. 6 and 7, the display device 200 according to the second embodiment may adopt the features of the display device 100 of FIGS. 1 to 4. For example, the second embodiment may include a main opening 117a-1 and an auxiliary opening 117a-2 extending from the main opening 117a-1.

Referring to FIGS. 6 and 7, the plurality of assembly wirings 220 may include a plurality of first assembly wirings 221 and a plurality of second assembly wirings 122. Both the plurality of first assembly wirings 221 and the plurality of second assembly wirings 122 may be disposed on the second passivation layer 115. That is, the first assembly wiring 221 and the second assembly wiring 122 may be arranged on the same layer. When the display device 200 is driven, the same low-potential voltage may be applied as alternating current to the plurality of first assembly wirings 221 and the plurality of second assembly wirings 122. The plurality of first assembly wirings 221 and the plurality of second assembly wirings 122 may be alternately arranged. And, in each of the plurality of sub pixels SP, one first assembly wiring 221 and one second assembly wiring 122 may be arranged adjacent to each other.

The plurality of first assembly wirings 221 include a first conductive layer 221a and a first clad layer 221b, and the plurality of second assembly wirings 122 may include a second conductive layer 122a and a second clad layer 122b. The first conductive layer 221a and the second conductive layer 122a may be disposed on the second passivation layer 115. The first clad layer 221b and the second clad layer 122b may be in contact with the first conductive layer 221a and the second conductive layer 122a, respectively. For example, the first clad layer 221b may be arranged to cover the top and side surfaces of the first conductive layer 221a, and the second clad layer 122b may be disposed to cover the top and side surfaces of the second conductive layer 122a. And the first conductive layer 221a and the second conductive layer 122a may have a thickness greater than the first clad layer 221b and the second clad layer 122b.

Next, the third passivation layer 216 is disposed on the first assembly wiring 221 and the second assembly wiring 122. The third passivation layer 216 is an insulating layer to protect the structure below the third passivation layer 216. Additionally, the third passivation layer 216 may function as an insulating layer to prevent short circuit defects due to migration between the first assembly wiring 221 and the second assembly wiring 122 when manufacturing the display device 200. Accordingly, the plurality of first assembly wirings 221 and the plurality of second assembly wirings 122 may be arranged to be spaced apart from each other with the third passivation layer 216 interposed therebetween.

Next, the second planarization layer 117 may be disposed on the third passivation layer 216. The second planarization layer 117 includes a plurality of first openings 117a on which each of the plurality of light emitting devices LED is seated, and a plurality of second openings 117b exposing each of the plurality of connection electrodes 123. At this time, the plurality of first openings 117a include a main opening 117a-1 and an auxiliary opening 117a-2, similar to the display device 100 of FIGS. 2 to 4.

A plurality of light emitting devices LED may be disposed in the plurality of first openings 117a. The plurality of light emitting devices LED may include a red light emitting device 230 placed in a red sub pixel SPR, a green light emitting device (240) placed in a green sub pixel SPG and a blue light emitting device 250 placed in blue sub pixel SPB.

Referring to FIGS. 6 and 7, the red light emitting device 230 disposed in the red sub pixel SPR may have a second semiconductor layer 133 disposed on the first semiconductor layer 131. The light emitting layer 132 that emits red light is disposed between the first semiconductor layer 131 and the second semiconductor layer 133. The first electrode 234 may be placed on the bottom of the first semiconductor layer 131, and the second electrode 135 may be placed on the top of the second semiconductor layer 133.

At this time, the red light emitting device 230 may include a first semiconductor layer 131 having a bottom surface area larger than the top surface of the first electrode 234. That is, the first electrode 234 has a smaller planar area than the first semiconductor layer 131. The first electrode 234 overlaps only a portion of the area where the red light emitting device 230 is in contact with the third passivation layer 216, and in the remaining area, the first semiconductor layer 131 and the third passivation layer 216 may be in contact.

Meanwhile, the first electrode 234 of the red light emitting device 230 may be arranged asymmetrically with respect to the center of the first semiconductor layer 131. That is, the first electrode 234 may be arranged asymmetrically with respect to the center of the plane of the red light emitting device 230. In addition, the first electrode 234 is arranged asymmetrically, and the end of the first electrode 234 is arranged on the same plane as the end of the first semiconductor layer 131 or may protrude outward from the end of the first semiconductor layer 1310. At this time, the auxiliary opening 117a-2 may be arranged adjacent to the end of the asymmetrically arranged first electrode 234.

In addition, the red light emitting device 230 may additionally include a protective film 136. The protective film 136 may surround a portion of the first semiconductor layer 131, the light emitting layer 132, and the second semiconductor layer 133. Forming the protective film 135 to protect the first semiconductor layer 131, the light emitting layer 132, and the second semiconductor layer 133 of the red light emitting device 230, and short circuit defects may be prevented when forming contact electrodes CE and pixel electrodes PE, which will be described later. The protective film 136 may cover at least a side surface of the red light emitting device 230 among the outer surfaces of the red light emitting device 230. For example, the protective film 136 may be disposed to cover the side and top surface of the first semiconductor layer 131, the side surface of the light emitting layer 132, the top surface of the first semiconductor layer 131 and the second electrode 135 protruding outward from the second semiconductor layer 133. However, the protective film 136 may cover only the side surface of the second semiconductor layer 133 and the side surface of the light emitting layer 132, or may also cover a portion of the side surface of the first semiconductor layer 131, but is not limited thereto. FIGS. 6 and 7 describe the red light emitting device 230, but the green light emitting device and the blue light emitting device may also be formed in the same structure and shape as the red light emitting device 230.

A contact electrode CE may be placed inside the first opening 117a. The contact electrode CE is an electrode that electrically connects the first assembly wiring 221 overlapping the first opening 117a with the first electrode 234 of the red light emitting device 230. After forming a contact hole exposing the first assembly wiring 221 in a portion of the third passivation layer 216 overlapping the first opening 117a, by forming a contact electrode CE inside the first opening 117a, the first electrode 234 of the red light emitting device 230 and the first assembly wiring 221 may be electrically connected.

The contact electrode CE may contact the side of the second planarization layer 117 at the first opening 117a, and the first clad layer 221b of the first assembly wiring 221 exposed from the third passivation layer 216 at the first opening 117a. Additionally, the contact electrode CE may be disposed on the side of the first semiconductor layer 131, the side of the light emitting layer 132, and the side of the second semiconductor layer 133. However, the contact electrode CE is not disposed on the upper portion of the second semiconductor layer 133 protruding outside the second electrode 135 or on the side of the second electrode 135. In this case, short circuit defects occurring when the contact electrode CE and the second electrode 135 are electrically connected may be prevented by the protective film 136 surrounding the light emitting layer 132, the second semiconductor layer 133, and the second electrode 135.

Meanwhile, the contact electrode CE may be made of a conductive material, such as copper (Cu), aluminum (Al), molybdenum (Mo), nickel (Ni), titanium (Ti), chromium (Cr), or an alloy thereof. At this time, when the contact electrode CE is made of a conductive material with excellent reflective properties, among the light emitted from the light emitting device LED, the light directed to the side of the light emitting device LED may be reflected to the upper portion of the light emitting device LED by the contact electrode CE, so there is a technical effect that may improve light efficiency.

In the display device 200 according to the second embodiment, at least some of the assembly wiring 220 for self-assembly of a plurality of light emitting devices LED may be used as wiring for applying a low-potential power supply voltage to the plurality of light emitting devices LED. In other words, instead of separately forming a wiring that supplies low-potential voltage and connecting it to a plurality of self-assembled light emitting devices LED, by electrically connecting the first assembly wiring 221 and the first electrode 234 of the light emitting device 230 through a contact electrode CE, so there is a technical effect in that a plurality of assembly wirings 220 may be used as wiring for supplying low-potential voltage to a plurality of light emitting devices LED when driving the display device 200.

In the display device 200 according to the second embodiment, the plurality of assembly wirings 220 include a clad layer, so that corrosion of the plurality of assembly wirings 220 or short circuit defects may be reduced. That is, each of the first conductive layer 221a of the plurality of first assembly wirings 221 and the second conductive layer 122a of the plurality of second assembly wirings 122 is covered with the second passivation layer 115, the first clad layer 221b, and the second clad layer 122b, so there is a technical effect that may improve the reliability of the plurality of assembly wiring 220.

Additionally, in the display device 200 according to the second embodiment, a plurality of first assembly wirings 221 and a plurality of second assembly wirings 122 may be arranged on the same layer. That is, both the plurality of first assembly wirings 221 and the plurality of second assembly wirings 122 may be disposed on the second passivation layer 115. Accordingly, the distance between the light emitting device LED and the first assembly wiring 221 may be substantially the same as the distance between the light emitting device LED and the second assembly wiring 122. Accordingly, in the display device 200 according to the second embodiment, there is a technical effect in that the electric field imbalance phenomenon that may occur when a light emitting device LED is placed relatively close to either the first assembly wiring 221 or the second assembly wiring 122 may be resolved.

In addition, in the display device 200 according to the second embodiment, the first electrode 234 of the light emitting device LED, for example, the red light emitting device 230, has a smaller area on the plane than the first semiconductor layer. That is, the bottom surface of the first semiconductor layer 131 may be wider than the top surface of the first electrode 234. Accordingly, in the display device 200 according to the second embodiment, the vertical electric field between the first electrode 234 and the plurality of assembly wiring 220 may be reduced, so there is a technical effect in that the phenomenon of a light emitting device LED riding on the side of the second planarization layer 117 may be minimized by widening the electric field gradient.

In addition, the display device 200 according to the second embodiment, the first opening 117a where the light emitting device LED is inserted includes a main opening 117a-1 corresponding to the shape and size of the light emitting device LED and an auxiliary opening 117a-2 extending from the main opening 117a-1. The auxiliary opening 117a-2 is smaller than the main opening 117a-1, so a light emitting device LED is not inserted, but in the area where the auxiliary opening 117a-2 is placed, sufficient space may be secured between the light emitting device LED and the second planarization layer 117. Accordingly, the third passivation layer 216 may be removed more comfortably in the space secured by the main opening 117a-1 and the auxiliary opening 117a-2, accordingly, there is a technical effect of securing the connection between the first electrode 234 of the light emitting device LED and the first assembly wiring 221 through the contact electrode CE.

Meanwhile, in the display device 200 according to the second embodiment, the first electrode 234 may be asymmetrically disposed with respect to the center of the first semiconductor layer 131. And, not only is the first electrode 234 disposed asymmetrically, but the end of the first electrode 234 may be disposed on the same plane as the end of the first semiconductor layer 131 or may protrude outward from the end of the first semiconductor layer 131. At this time, as the auxiliary opening 117a-2 is placed adjacent to the end of the first electrode 234, even if the first electrode 234 is arranged asymmetrically, the auxiliary opening 117a-2 may alleviate the electric field asymmetry phenomenon. If the first electrode 234 of the light emitting device 230 is arranged asymmetrically and biased to one side, the electric field may be excessively focused on the corresponding area.

However, when the auxiliary opening 117a-2 is placed in the direction in which the first electrode 234 is placed, since the auxiliary opening 117a-2 may secure sufficient space between the light emitting device 230 and the second planarization layer 117, electric field asymmetry that may occur between the first electrode 234 and the second planarization layer 117 may be alleviated. In other words, the intensity per unit area of the electric field that may occur between the second planarization layer 117 and the first electrode 234 is reduced, so the electric field asymmetry phenomenon may be weakened.

Therefore, in the display device 200 according to the second embodiment, there is a technical effect that assembly defects, such as the light emitting device LED getting on the second planarization layer 117, may be improved due to the asymmetrical electric field.

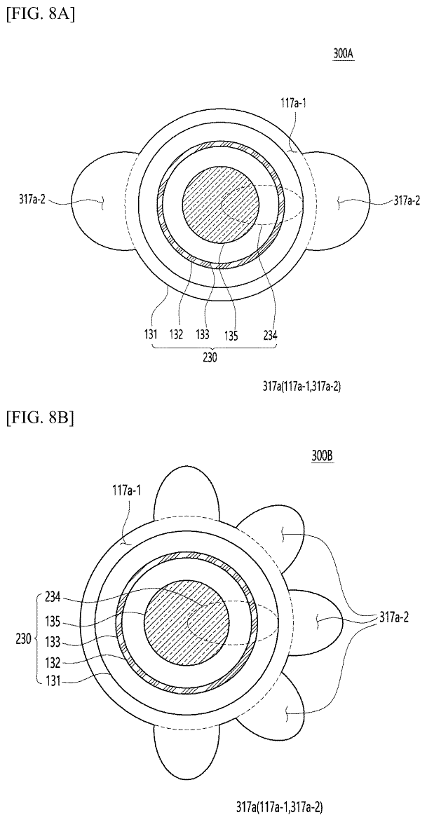

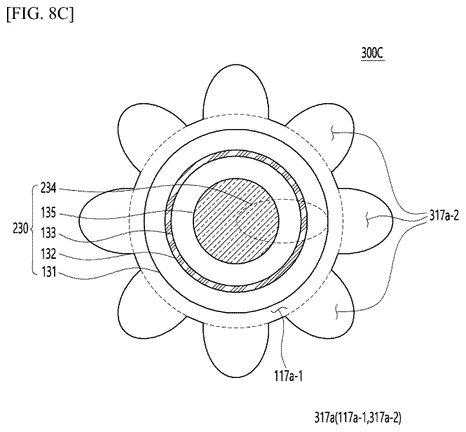

FIGS. 8A to 8C are enlarged plan views of display devices according to third to fifth embodiments. The display devices 300A, 300B, and 300C of FIGS. 8A to 8C further include a plurality of auxiliary openings 317a-2 compared to the display device 200 of FIGS. 6 and 7, and this will be mainly described.

In FIGS. 8A to 8C, for convenience of explanation, only the first opening and the red light emitting device are shown among the various configurations of the display devices 300A, 300B, and 300C.

A plurality of first openings 317a may be disposed in each of a plurality of sub pixels SP. Each of the plurality of first openings 317a may include a main opening 117a-1 and a plurality of auxiliary openings 317a-2. At this time, the first openings in one sub pixel SP 317a may be multiple.

The main opening 117a-1 is an opening into which a plurality of light emitting devices LED are inserted. At this time, the main opening 117a-1 and the plurality of light emitting devices LED may have circular or oval shapes that correspond to each other on a plane, as shown in FIGS. 8A to 8C.

The auxiliary opening 317a-2 may be connected to the main opening 117a-1. At this time, the auxiliary openings 317a-2 connected to one main opening 117a-1 may be multiple.

At this time, the plurality of auxiliary openings 317a-2 may be arranged to be at least adjacent to the end of the first electrode 234 of the red light emitting device 230. That is, when the first electrode 234 of the red light emitting device 230 is asymmetrically disposed, a plurality of auxiliary openings 317a-2 may be disposed in the area where the first electrode 234 is disposed. In addition, when the main opening 117a-1 and the light emitting device LED have a circular or oval shape on a plane, the plurality of auxiliary openings 317a-2 may be arranged to surround the main opening 117a-1. Meanwhile, the green light emitting device and the blue light emitting device are not shown in the drawing, but the first opening 317a where the green light emitting device and the blue light emitting device are arranged may also be applied in the same way.

Specifically, referring to FIG. 8A, the first opening 317a may include a main opening 117a-1 and two auxiliary openings 317a-2. One of the auxiliary openings 317a-2 may be placed adjacent to the end of the first electrode 234. The remaining auxiliary opening 317a-2 may be placed on the opposite side from the main opening 117a-2. Accordingly, even if the first electrode 234 is disposed opposite to the expected position during the assembly process of the red light emitting device 230, sufficient space may be secured between the red light emitting device 230 and the second planarization layer 117 by the auxiliary opening 317a-2.

Next, referring to FIG. 8B, the first opening 317a may include a main opening 117a-1 and three or more auxiliary openings 317a-2. In FIG. 8B, there are five auxiliary openings 317a-2, but the number is not limited thereto. A plurality of auxiliary openings 317a-2 may be arranged adjacent to the end of the asymmetrically arranged first electrode 234 as shown in FIG. 8B. Additionally, a plurality of auxiliary openings 317a-2 may be arranged to surround approximately half of the circumference of the main opening 117a-1, which has a circular or oval shape.

Referring to FIG. 8C, the first opening 317a may include a main opening 117a-1 and three or more auxiliary openings 317a-2. In FIG. 8C, there are eight auxiliary openings 317a-2, but the number is not limited thereto. The plurality of auxiliary openings 317a-2 may be arranged to surround the circumference of the main opening 117a-1 having a circular or oval shape, and as shown in FIG. 8C, it may be arranged to surround the entire circumference of the main opening 117a-1.

Therefore, in the display devices 300A, 300B, and 300C according to the third to fifth embodiments, since the first opening 317a includes a main opening 117a-1 and a plurality of auxiliary openings 317a-2, even if the first electrode 234 is partially rotated and placed at a desired position during the assembly process, the space between the second planarization layer 117 and the first electrode 234 may be secured. The plurality of auxiliary openings 317a-2 are smaller than the main opening 117a-1, so a light emitting device LED is not inserted, but there is a technical effect of securing a more sufficient space between the light emitting device LED and the second planarization layer 117 in the area where the plurality of auxiliary openings 317a-2 are arranged.

Therefore, during the assembly process of the light emitting device LED, the light emitting device LED is inserted into the desired position, but even if the first electrode 234 is rotated and placed at the desired position, the plurality of auxiliary openings 317a-2 are arranged and the auxiliary openings 317a-2 are arranged to surround the main opening 117a-1, thereby a gap between the first electrode 234 and the second planarization layer 117 may be secured.

Accordingly, in the display devices 300A, 300B, and 300C according to the third to fifth embodiments, there is a technical effect in that a sufficient contact area between the light emitting device LED and the third passivation layer 216 may be secured and assembly defects may be improved.

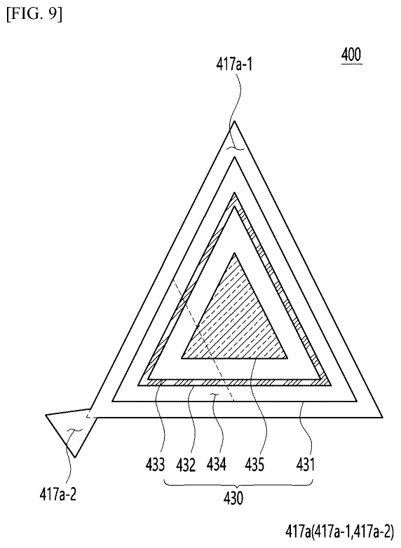

FIG. 9 is a schematic enlarged plan view of a display device according to the sixth embodiment. Referring to FIG. 9, the display device 400 according to the sixth embodiment may adopt the features of the display device 200 of FIGS. 6 and 7. For example, it may include a main opening 417a-1 and an auxiliary opening 417a-2 extending from the main opening 417a-1. In particular, compared to the second embodiment, the planar shapes of the first opening 417a and the red light emitting device 430 are different, and the description will focus on this. In FIG. 9, for convenience of explanation, only the first opening and the red light emitting device are shown among the various components of the display device 400.

Referring to FIG. 9, each of the plurality of first openings 417a may include a main opening 417a-1 and a plurality of auxiliary openings 417a-2. The main opening 417a-1 is an opening into which a plurality of light emitting devices LED are inserted. The main opening 417a-1 and the plurality of light emitting devices LED may have the same polygonal shape on a plane. Referring to FIG. 9, the main opening 417a-1 and the red light emitting device 430 may have a triangular shape on a plane, but are not limited thereto.

The red light emitting device 430 includes a first semiconductor layer 431, a second semiconductor layer 433, a light emitting layer 432 disposed between the first semiconductor layer 431 and the second semiconductor layer 433, a first electrode 434 disposed on the bottom surface of the first semiconductor layer 431 and a second electrode 435 disposed on the top surface of the second semiconductor layer 433. Compared to the red light emitting device 130 in the display device 200 according to the second embodiment, the first semiconductor layer 431, the second semiconductor layer 433, the light emitting layer 432, and the second electrode 435 are different in that they are triangular in planar shape, and the description will focus on this. The first electrode 434 has a smaller planar area than the first semiconductor layer 431. That is, the area of the bottom surface of the first semiconductor layer 431 may be larger than the top surface of the first electrode 434. Additionally, the first electrode 434 may be arranged adjacent to one vertex of the triangular red light emitting device 430 on a plane. In FIG. 9, the end of the first electrode 434 is shown as being disposed on the same plane as the end of the first semiconductor layer 431, but it may protrude outward from the end of the first semiconductor layer. Meanwhile, the green light emitting device and the blue light emitting device are not shown in the drawing, but the first opening where the green light emitting device and the blue light emitting device and the green light emitting device and the blue light emitting device are arranged may also be applied in the same way.

The auxiliary opening 417a-2 may be connected to the main opening 417a-1. At this time, there may be one auxiliary opening 417a-2 connected to one main opening 417a-1.

Referring to FIG. 9, the auxiliary opening 417a-2 may be connected to the main opening 417a-1 into which a light emitting device LED is inserted. However, the auxiliary opening 417a-2 is smaller than the main opening 417a-1, so the plurality of light emitting devices LED may not be inserted. At this time, the planar shape of the auxiliary opening 417a-2 may correspond to the planar shape of the main opening 417a-1. That is, the auxiliary opening 417a-2 may have a polygonal shape on a plane. Referring to FIG. 9, the auxiliary opening 417a-2 may have a triangular shape on a plane, but is not limited thereto.

Additionally, when the main opening 417a-1 and a plurality of light emitting devices LED have a polygonal shape, the auxiliary opening 417a-2 may be arranged to be connected to one of the plurality of vertices of the main opening 417a-1. Referring to FIG. 9, the auxiliary opening 417a-2 may be arranged to be connected to one of the three vertices of the main opening 417a-1 having a triangular shape in a plane. However, it is not limited to this At this time, the first electrode 434 of the red light emitting device 430 may be placed adjacent to the auxiliary opening 417a-2.

In the display device 400 according to the sixth embodiment, a light emitting device LED may be formed in a triangular shape on a plane. Since a light emitting device LED has a very small size in the micrometer unit, when manufacturing a light emitting device LED, it is more advantageous in terms of the process to manufacture the light emitting device LED in a polygonal shape than to manufacture it in a circular shape on a plane. In other words, if the side of the light emitting device LED is flat rather than curved, the cutting process, etc. when manufacturing the light emitting device LED may be more advantageous. Accordingly, the display device 400 according to the sixth embodiment has the technical effect of enabling the light emitting device LED to be manufactured more easily by forming the light emitting device LED into a triangular shape on a plane.

Additionally, in the display device 400 according to the sixth embodiment, the light emitting device LED may be assembled more accurately at a desired location through the main opening 417a-1 corresponding to the light emitting device LED having a triangular shape on a plane. That is, when both the light emitting device LED and main opening 417a-1 are triangles, in the process of assembling a light emitting device LED, the probability that the light emitting device LED is rotated and assembled in an undesirable position may be reduced. Accordingly, the display device 400 according to the sixth embodiment has the technical effect of improving the assembly rate of the light emitting device.

Additionally, in the display device 400 according to the sixth embodiment, as the auxiliary opening 417a-2 is placed adjacent to the end of the first electrode 434, even if the first electrode 434 is placed asymmetrically, the auxiliary opening 417a-2 may alleviate the electric field asymmetry phenomenon. That is, when the auxiliary opening 417a-2 is placed in the direction in which the first electrode 434 is placed, the auxiliary opening 417a-2 may secure sufficient space between the light emitting device LED and the second planarization layer 117, so electric field asymmetry that may occur between the first electrode 434 and the second planarization layer 117 may be alleviated.

In other words, the intensity per unit area of the electric field that may occur between the second planarization layer 117 and the first electrode 434 is reduced, so the electric field asymmetry phenomenon may be weakened. Therefore, in the display device 400 according to the sixth embodiment, there is a technical effect that assembly defects, such as the light emitting device (LED) getting on the second planarization layer 117, may be improved due to the asymmetrical electric field.

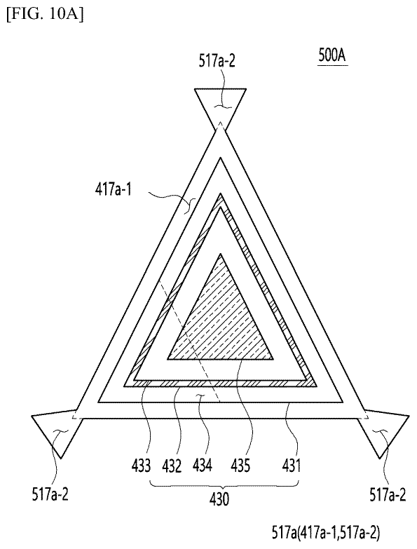

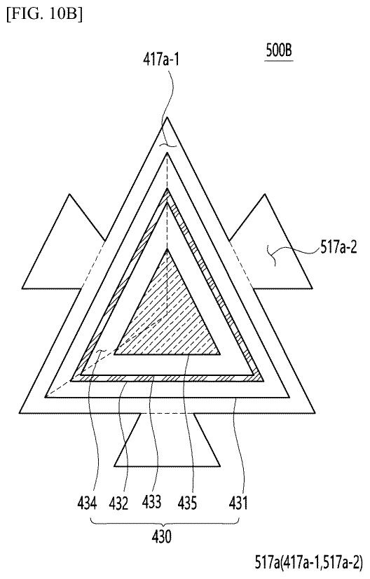

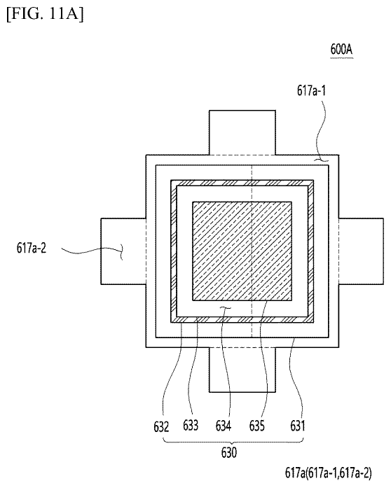

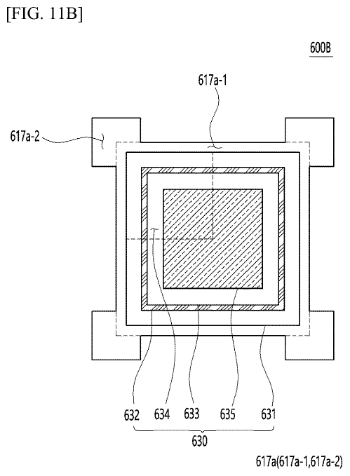

FIGS. 10A to 11B are enlarged plan views of display devices according to seventh and eighth embodiments.

The display devices 500A and 500B of FIGS. 10A and 10B are different from the display device 400 of FIG. 9 in a plurality of auxiliary openings 517a-2, and the display devices 600A and 600B of FIGS. 11A and 11B have a different first opening 617a compared to the display device 400 of FIG. 9, and the description will focus on this. In FIGS. 10A to 11B, for convenience of explanation, only the first opening and the red light emitting device are shown among the various configurations of the display devices 500A, 500B, 600A, and 600B.

First, referring to FIGS. 10A and 10B, a plurality of first openings 517a are disposed in each of a plurality of sub pixels SP. Each of the plurality of first openings 517a may include a main opening 417a-1 and a plurality of auxiliary openings 517a-2. At this time, first openings 517a in one sub pixel SP may be multiple.

The main opening 417a-1 is an opening into which a plurality of light emitting devices LED are inserted. At this time, the main opening 417a-1 and the plurality of light emitting devices LED may have a triangular shape on a plane.

The auxiliary opening 517a-2 may be connected to the main opening 417a-1. At this time, the auxiliary openings 517a-2 connected to one main opening 417a-1 may be multiple.

First, referring to FIG. 10A, the first opening 517a may include a main opening 417a-1 and three auxiliary openings 517a-2. Each of the three auxiliary openings 517a-2 may be arranged to correspond to the three vertices of the triangular main opening 417a-1.

Next, referring to FIG. 10B, the first electrode 434 of the red light emitting device 430 has a smaller area on the plane than the first semiconductor layer 431. That is, the area of the bottom surface of the first semiconductor layer 431 may be larger than the top surface of the first electrode 434. Additionally, the first electrode 434 may be arranged adjacent to one side of the triangular red light emitting device 430 in a plane view. In FIG. 10B, the end of the first electrode 434 is shown as being disposed on the same plane as the end of the first semiconductor layer 431, but it may protrude outward from the end of the first semiconductor layer 431.

At this time, each of the three auxiliary openings 517a-2 may be arranged to correspond to the three sides of the triangular main opening 417a-1.

Therefore, in the display devices 500A and 500B according to the seventh and eighth embodiments, since the first opening 517a includes a main opening 417a-1 and a plurality of auxiliary openings 517a-2, even if the first electrode 434 is partially rotated and placed at a desired position during the assembly process, a space between the second planarization layer 117 and the first electrode 434 may be secured.

Since the light emitting device LED is triangular in shape, and the main opening 417a-1 is also triangular in shape, when a light emitting device LED is assembled and placed in the main opening, there are three cases in which the first electrode 434 may be rotated and placed. That is, the light emitting device LED may be arranged in three cases, including when the first electrode 434 is arranged corresponding to the vertex and when it is arranged corresponding to the side.

Accordingly, in the display devices 500A and 500B according to the seventh and eighth embodiments, as the plurality of auxiliary openings 517a-2 are all arranged in correspondence with the vertices or sides, even if the first electrode 434 is rotated and assembled at a desired position during the assembly process, there is a technical effect of securing the space between the second planarization layer 117 and the first electrode 434.

In addition, the plurality of auxiliary openings 517a-2 are smaller than the main opening 417a-1, so a light emitting device LED is not inserted, but in the area where the plurality of auxiliary openings 517a-2 are arranged, a more sufficient space may be secured between the light emitting device LED and the second planarization layer 117. Accordingly, in the assembly process of a light emitting device LED, the light emitting device LED may be inserted into the desired location, but even if the first electrode 434 is rotated and placed at the desired position, a gap between the first electrode 434 and the second planarization layer 117 may be secured by the auxiliary opening 517a-2 is arranged in plural and arranged to correspond to all vertices of the main opening 417a-1 or arranged to correspond to all sides.

Accordingly, in the display devices 500A and 500B according to the seventh and eighth embodiments, there is a technical effect in that a sufficient contact area between the light emitting device LED and the third passivation layer 216 may be secured and assembly defects may be improved.

Next, FIGS. 11A and 11B are enlarged plan views of display devices 600A and 600B according to the ninth and tenth embodiments. Referring to FIGS. 11A and 11B, each of the plurality of first openings 617a may include a main opening 617a-1 and a plurality of auxiliary openings 617a-2. The main opening 617a-1 is an opening into which a plurality of light emitting devices LED are inserted. The main opening 617a-1 and the plurality of light emitting devices LED may have the same polygonal shape on a plane. Referring to FIGS. 11A and 11B, the main opening 617a-1 and the red light emitting device 630 may have a rectangular shape on a plane, but are not limited thereto.

The red light emitting device 630 may include a first semiconductor layer 631, a second semiconductor layer 633, a light emitting layer 632 disposed between the first semiconductor layer 631 and the second semiconductor layer 633, a first electrode 634 disposed on a bottom surface of the first semiconductor layer 631 and a second electrode 635 disposed on a top surface of the second semiconductor layer 633.

Compared to the red light emitting device 130 of FIGS. 6 and 7 according to the second embodiment, the red light emitting device 630 of the display devices 600A and 600B according to the ninth and tenth embodiments is different in that the first semiconductor layer 631, the second semiconductor layer 633, the light emitting layer 632, and the second electrode 635 are square in planar shape, and the description will focus on this.

In the red light emitting device 630, the first electrode 635 has a smaller planar area than the first semiconductor layer 631. That is, the area of the bottom surface of the first semiconductor layer 631 may be larger than the top surface of the first electrode 635. Additionally, the first electrode 635 may be arranged adjacent to one side of the square-shaped red light emitting device 630 on a plane, as shown in FIG. 11A, and as shown in FIG. 11B, it may be arranged adjacent to one vertex of the square-shaped red light emitting device 630 on a plane. In FIGS. 11A and 11B, the end of the first electrode 634 is shown as being disposed on the same plane as the end of the first semiconductor layer 631, but it may protrude outward from the end of the first semiconductor layer 631.

Meanwhile, the green light emitting device and the blue light emitting device are not shown in the drawing, and the first opening where the green light emitting device and the blue light emitting device and the green light emitting device and the blue light emitting device are arranged may also be applied in the same way.

The auxiliary opening 617a-2 may be connected to the main opening 617a-1. At this time, the auxiliary openings 617a-2 connected to one main opening 617a-1 may be multiple.

The main opening 617a-1 is an opening into which a plurality of light emitting devices LED are inserted. At this time, the main opening 617a-1 and the plurality of light emitting devices LED may have a square shape on a plane.

The auxiliary opening 617a-2 may be connected to the main opening 617a-1. At this time, the auxiliary openings 617a-2 connected to one main opening 617a-1 may be multiple.

First, referring to FIG. 11A, the first opening 617a may include a main opening 617a-1 and four auxiliary openings 617a-2. Each of the four auxiliary openings 617a-2 may be arranged to correspond to the four sides of the square-shaped main opening 617a-1.

Next, referring to FIG. 11B, each of the four auxiliary openings 617a-2 may be arranged to correspond to the four vertices of the square-shaped main opening 617a-1.

Therefore, in the display devices 600A and 600B according to the ninth and tenth embodiments, since the first opening 617a includes a main opening 617a-1 and a plurality of auxiliary openings 617a-2, even if the first electrode 634 is partially rotated and placed in the desired position during the assembly process, the space between the second planarization layer 117 and the first electrode 634 may be secured. Since the light emitting device LED is square-shaped, and the main opening 617a-1 is also square-shaped, when a light emitting device LED is assembled and placed in the main opening 617a-1, there are a total of four cases in which the first electrode 634 may be rotated and placed. That is, the light emitting device LED may be arranged in four cases, including when the first electrode 634 is arranged corresponding to the vertex and when it is arranged corresponding to the side. Accordingly, in the display devices 600A and 600B according to the ninth and tenth embodiments, as the plurality of auxiliary openings 617a-2 are all arranged in correspondence with the vertices or sides, even if the first electrode 634 is rotated and assembled at a desired position during the assembly process, the space between the second planarization layer 117 and the first electrode 634 may be secured.

In addition, the plurality of auxiliary openings 617a-2 are smaller than the main opening 617a-1, so a light emitting device LED is not inserted, but in the area where the plurality of auxiliary openings 617a-2 are arranged, a more sufficient space may be secured between the light emitting device LED and the second planarization layer 117. Accordingly, during the assembly process of the light emitting device LED, the light emitting device LED is inserted into the desired location, but even if the first electrode 634 is rotated and placed at the desired position, plurality of auxiliary openings 617a-2 are placed, a gap between the first electrode 634 and the second planarization layer 117 may be secured by being arranged to correspond to all vertices or all sides of the main opening 617a-1. Accordingly, in the display devices 600A and 600B according to the ninth and tenth embodiments, a sufficient contact area between the light emitting device LED and the third passivation layer 216 may be secured, and assembly defects may be improved.

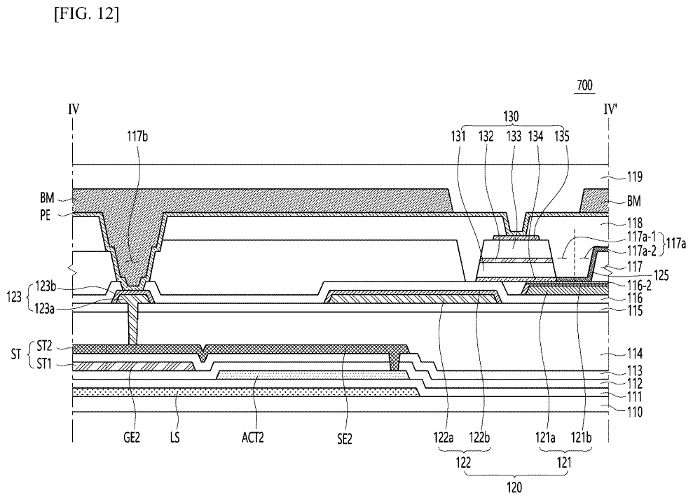

Next, FIG. 12 is a cross-sectional view of the display device 700 according to the 11th embodiment. The display device 700 according to the 11th embodiment may adopt the features of FIGS. 6 and 7. For example, it may include a main opening 117a-1 and an auxiliary opening 117a-2 extending from the main opening 117a-1. Hereinafter, the description will focus on the form in which the display device includes side wiring.

Meanwhile, in internal research, when forming side wiring in a light emitting device, if the area of the first opening 117a where the light emitting device is assembled is not sufficiently secured, there was a problem that the side wiring was not formed uniformly.

Referring to FIG. 12, the display device 700 according to the 11th embodiment includes a main opening 117a-1 and an auxiliary opening 117a-2 extending from the main opening 117a-1. The first assembly wiring 121 and the second assembly wiring 122 may be arranged on the second passivation layer 115 to overlap the opening area where the light emitting device 130 is assembled. The second insulating layer 116-2 may be disposed on the first clad layer 121b of the first assembly wiring 121.

And the side wiring 125 is placed within the opening 117a-1 so that it may be electrically connected to the first electrode 134 of the light emitting device 130, and it may be in contact with the side wall of the opening 117a-1.

The eleventh embodiment includes an auxiliary opening 117a-2, since the light emitting device 130 is assembled in the assembly hall and the remaining area is sufficiently secured, there is a technical effect of uniformly forming side wiring that is electrically connected to the first electrode 134 of the light emitting device 130, and there is a technical effect of reducing process steps by eliminating the need to ash the partition wall on the side of the assembly hole.

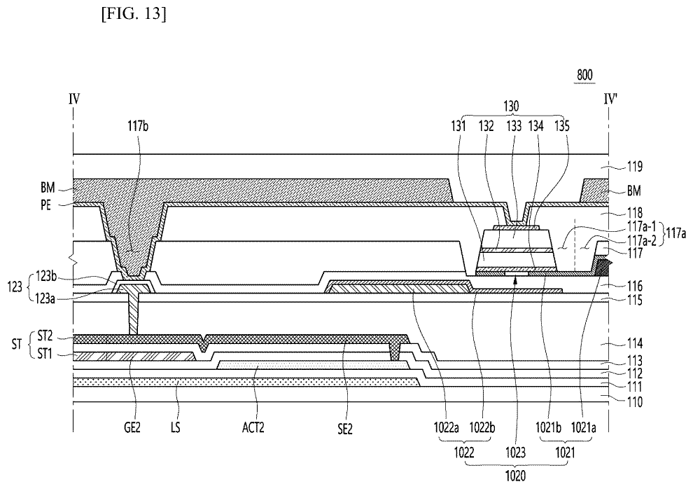

FIG. 13 is a cross-sectional view of the display device 800 according to the twelfth embodiment. The display device 800 according to the twelfth embodiment may adopt the features of FIGS. 6 and 7. For example, it may include a main opening 117a-1 and an auxiliary opening 117a-2 extending from the main opening 117a-1. Hereinafter, the explanation will focus on the differences in the shape of the assembly wiring 1020.

Referring to FIG. 13, the first clad layer 1021b of the first assembly wiring 1021 may extend from the first conductive layer 1021a toward the second assembly wiring 1022. Additionally, the second clad layer 1022b of the second assembly wiring may extend from the second conductive layer 1022a toward the first assembly wiring 1021.

In the twelfth embodiment, the first clad layer 1021b and the second clad layer 1022b are disposed with the third passivation layer 116 therebetween, and may overlap top and bottom.

Meanwhile, the first clad layer 1021b may be provided with a predetermined electrode hole 1023 in an area overlapping with the light emitting device 130 and the second clad layer 1022b. The width of the electrode hole 1023 may be smaller than the width of the light emitting device 130.

Additionally, an alternating current voltage may be applied to the first clad layer 1021b and the second clad layer 1022b to form an electric field. The DEP force caused by this electric field may be concentrated in the electrode hole 1023 provided in the second clad layer 1022b. The light emitting device 130 may be self-assembled within the first opening 117a by concentrated dielectrophoretic force (DEP force).

There is a technical effect of strengthening the assembly force for the light emitting device 130 due to the vertical overlap of the assembly wiring 1021 and 1022. In addition, the first opening 117a does not vertically overlap the first conductive layer 1021a and the second conductive layer 1022a, which has the technical effect of reducing the thickness of the panel.

Meanwhile, the second clad layer 1022b may be disposed below the light emitting device 130. Additionally, the first clad layer 1021b may be in contact with the first electrode 134 of the light emitting device 130.

Accordingly, as the second clad layer 1022b is disposed on the bottom surface of the first electrode 134 of the light emitting device 130, the light emitting devices 130 are supported uniformly and have a wide electrical contact area between the light emitting elements 130, thereby improving carrier injection efficiency, resulting in a complex technical effect of improving luminous efficiency and brightness.

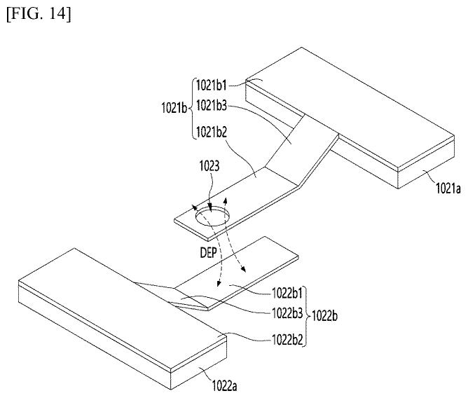

FIG. 14 is a diagram showing assembly wiring 1020 in detail in the display device 800 according to the twelfth embodiment.

Referring to FIG. 14, in the twelfth embodiment, a portion of the first clad layer 1021b and a portion of the second clad layer 1022b may overlap top and bottom. For example, the first clad layer 1021b may include a 1-1 clad layer 1021b1, a first-second clad layer 1021b2, and a first-third clad layer 1021b3. The first-second clad layer 1021b2 may be a protruding electrode extending from the 1-1 clad layer 1021b1 toward the second clad layer 1022b.

Additionally, the second clad layer 1022b may include a second-first clad layer 1022b1, a second-second clad layer 1022b2, and a second-third clad layer 1022b3. The second-second clad layer 1022b2 may be a protruding electrode extending from the second-first clad layer 1022b1 toward the first clad layer 1021b.

At this time, the first-second clad layer 1021b2 and the second-second clad layer 1022b2 may overlap vertically.

Additionally, the first-second clad layer 1021b2 may include an electrode hole 1023. Accordingly, the DEP force may be concentrated and formed in the electrode hole 1023 of the first clad layer 1021b, and the Dep force is distributed uniformly in the assembly hole 1023, which has the technical effect of improving the assembly force.

Additionally, the first-third clad layer 1021b3 connecting the 1-1 clad layer 1022b1 and the first-second clad layer 1021b2 may be arranged to have an inclined surface. Through this, the first conductive layer 1021a is disposed in an area other than the first opening 117a, which has the technical effect of reducing the thickness of the panel.

The display device including the semiconductor light emitting device according to the above-described embodiment has the technical effect of being able to utilize the wiring for self-assembly of the light emitting device as the wiring for driving the light emitting device.

In addition, the embodiment has the technical effect of minimizing defects during self-assembly or bonding of a light emitting device by forming the structure of a plurality of assembly wiring in various ways.

Additionally, the embodiment has the technical effect of minimizing corrosion and short circuit defects in a plurality of assembly wiring.

In addition, the embodiment has the technical effect of stably bonding a plurality of light emitting devices by reducing the step between the plurality of assembly wirings.

In addition, the embodiment has the technical effect of securing a wide electric field gradient by reducing the area of the first electrode of the light emitting device, thereby forming the electric field symmetrically.

In addition, the embodiment has the technical effect of reducing assembly defects of the light emitting device by preventing the electric field from being focused on the partition wall on the side of the opening by changing the shape of the first electrode and the opening of the light emitting device.

Additionally, the embodiment has the technical effect of forming uniform side wiring by changing the shape of the opening.

Additionally, the embodiment has the technical effect of improving the assembly force for a light emitting device by arranging a plurality of assembly wirings to overlap vertically.

The above detailed description should not be construed as restrictive in any respect and should be considered illustrative. The scope of the embodiments should be determined by reasonable interpretation of the appended claims, and all changes within the equivalent scope of the embodiments are included in the scope of the embodiments.

### EXPLANATION OF THE REFERENCES

10: Mother substrate AA: display area
NA: Non-display area SP: Sub pixel
SPR: Red sub pixel SPG: Green sub pixel
SPB: Blue sub pixel
100, 200, 300A, 300B, 300C 400, 500A, 500B, 600A, 600B, 700, 800: Display device
110: Substrate 111: Buffer layer
112: Gate insulating layer 113: First passivation layer
114: First planarization layer 115: Second passivation layer
116, 216: Third passivation layer 116-2: Second insulating layer
117: Second planarization layer 117a, 317a, 417a, 517a, 617a: First opening
117b: Second opening
117a-1, 417a-1, 617a-1: Main opening
117a-2, 317a-2, 417a-2, 517a-2, 617a-2: Auxiliary opening
118: Third planarization layer 119: Protective layer
120, 220, 1020: Assembly wiring 121, 221, 1021: First assembly wiring
121a, 221a, 1021a: First conductive layer 121b, 221b, 1021b: First clad layer
122, 1022: Second assembly wiring 122a, 1022a: Second conductive layer
122b, 1022b: Second clad layer 1021b1: First-first clad layer
1021b2: First-second clad layer 1021b3: First-third clad layer
1022b1: Second-first clad layer 1022b2: Second-second clad layer
1022b3: Second-third clad layer 1023: Electrode hole
123: Connection electrode 123a: First connection layer
123b: Second connection layer 125: Side wiring
LED: Light emitting device 130, 230, 430, 630: Red light emitting device
131, 431, 631: First semiconductor layer 132, 432, 632: Light emitting layer
133, 433, 632: Second semiconductor layer 134, 234, 434, 634: First electrode
135, 435, 635: Second electrode 140: Green light emitting device
150: Blue light emitting device LS: Light blocking layer
SL: Scan line DL: Data line
RL: Reference line VDD: high potential power supply wiring
VDD1: First layer VDD2: Second layer
VDD3: Third layer TRI: First transistor
ACT1: First active layer GE1: First gate electrode
SE1: First source electrode DE1: First drain electrode
TR2: Second transistor ACT2: Second active layer
GE2: Second gate electrode SE2: Second source electrode
DE2: Second drain electrode TR3: Third transistor
ACT3: Third active layer GE3: Third gate electrode
SE3: Third source electrode DE3: Third drain electrode
ST: Storage capacitor ST1: First capacitor electrode
ST2: Second capacitor electrode CE: Contact electrode
PE: Pixel electrode BM: Black matrix
CB: Chamber WT: Fluid
MG: Magnet PD: Assembly pad
PD1: First assembly pad PD2: Second assembly pad
PD3: Third assembly pad PD4: Fourth assembly pad
PD5: Fifth assembly pad PD6: Sixth assembly pad
PL: Assembly wiring connection part PL1: First connection part
PL2: Second connection PL3: Third connection
PL4: Fourth connection PL5: Fifth connection
PL6: sixth connection LL: Link Line
SCL: Scribing line IL: Plural insulating layers

### INDUSTRIAL APPLICABILITY

The embodiment may be adopted in the field of displays that display images or information.

The embodiment may be adopted in the field of displays that display images or information using a semiconductor light emitting device.

The embodiment may be adopted in the field of displays that display images or information using micro-or nano-level semiconductor light emitting devices.

1. A display device having a semiconductor light emitting device, comprising:
a substrate;
a first assembly wiring and a second assembly wiring arranged to be spaced apart from each other on the substrate;
a planarization layer disposed on the first assembly wiring and the second assembly wiring and having an opening overlapping the first assembly wiring and the second assembly wiring; and
a light emitting device disposed inside the opening and comprising a first electrode electrically connected to the first assembly wiring,
wherein the opening comprises a main opening and one or more auxiliary openings connected to the main opening and smaller than the main opening.

2. The display device according to claim 1, wherein the first assembly wiring is disposed above the second assembly wiring,
wherein the first electrode is in contact with the first assembly wiring, and
wherein the auxiliary opening is configured to overlap the first assembly wiring.

3. The display device according to claim 2, wherein an area where the first assembly wiring and the opening overlap is wider than an area where the second assembly wiring and the opening overlap.

4. The display device according to claim 1, wherein the first assembly wiring and the second assembly wiring are arranged on a same layer,
wherein the light emitting device further comprises a first semiconductor layer disposed on the first electrode and having a bottom surface area larger than the top surface area of the first electrode, and
wherein the first electrode is arranged asymmetrically with respect to a center of the first semiconductor layer.

5. The display device according to claim 4, wherein an end of the first electrode is disposed on a same plane as an end of the first semiconductor layer, or protrudes outward from the end of the first semiconductor layer.

6. The display device according to claim 5, wherein the auxiliary opening is arranged adjacent to the end of the first electrode.

7. The display device according to claim 4, further comprising:
a passivation layer disposed between the first assembly wiring, the second assembly wiring, and the light emitting device, and comprising a contact hole for exposing the first assembly wiring disposed between the light emitting device and the planarization layer; and
a contact electrode connecting the first electrode and the first assembly wiring through the contact hole.

8. The display device according to claim 4, wherein the main opening and the light emitting device are configured to have a circular or oval shape in a plane.

9. The display device according to claim 8, wherein the auxiliary opening is arranged in plural numbers to surround the circumference of the main opening.

10. The display device according to claim 4, wherein the main opening and the light emitting device are configured to have the same polygonal shape on a plane.

11. The display device according to claim 10, wherein the auxiliary opening is arranged to be connected to a plurality of vertices or a plurality of sides of the main opening.

12. A display device having a semiconductor light emitting device, comprising:
a substrate with a plurality of a sub pixels defined;
a plurality of a first assembly wirings arranged along the plurality of sub pixels arranged on a same line among the plurality of sub pixels;
a plurality of a second assembly wirings arranged along the plurality of sub pixels arranged on a same line among the plurality of sub pixels and arranged adjacent to each of the first assembly wirings;
a planarization layer comprising a plurality of pockets overlapping the plurality of first assembly wirings and the plurality of second assembly wirings; and
a plurality of light emitting devices disposed in the plurality of pockets in each of the plurality of sub pixels and comprising a lower electrode connected to the display device,
wherein each of the plurality of pockets comprises a first pocket having a first size and in which the plurality of light emitting devices are disposed, and a second pocket having a second size smaller than the first size and extending from the first pocket.

13. The display device according to claim 12, wherein the plurality of first assembly wirings are disposed above the plurality of second assembly wirings,
wherein the lower electrode is in contact with the plurality of first assembly wirings, and
wherein the second pocket overlaps the plurality of first assembly wiring,

14. The display device according to claim 12, wherein the plurality of first assembly wirings and the plurality of second assembly wirings are arranged on a same plane,

15. The display device according to claim 14, wherein the light emitting device comprises a first semiconductor layer disposed on the lower electrode,
wherein the lower electrode is configured to have a smaller planar area than the first semiconductor layer, and the lower electrode is arranged asymmetrically with respect to a center of the first semiconductor layer,

16. The display device according to claim 15, wherein an end of the lower electrode coincides with a side of the light emitting device or protrudes outward from the side of the light emitting device.

17. The display device according to claim 16, wherein the second pocket is disposed adjacent to the end of the lower electrode.

18. The display device according to claim 14, wherein the second pockets are arranged in plurality to surround the outside of the first pocket.

19. The display device according to claim 1, wherein the first assembly wiring and the second assembly wiring vertically overlap, and the first assembly wiring comprises an electrode hole in an area that vertically overlaps the second assembly wiring and the light emitting device,

20. A display device having a semiconductor light emitting device, comprising:
a substrate;
a first assembly wiring and a second assembly wiring arranged to be spaced apart from each other on the substrate;
a planarization layer disposed on the first assembly wiring and the second assembly wiring and having an opening overlapping the first assembly wiring and the second assembly wiring;
a light emitting device disposed within the opening and comprising a first electrode;
a side wiring disposed within the opening and electrically connected to the first electrode; and
wherein the opening comprises a main opening and one or more auxiliary openings connected to the main opening and smaller than the main opening, and
wherein the side wiring is disposed within the auxiliary opening and is in contact with a side wall of the opening.
